(19) United States
(12) Patent Application Publication
(10) Pub. No.: US 2025/0264425 A1
(43) Pub. Date: Aug. 21, 2025

(54) METHOD FOR DETERMINING HUFF AND PUFF FLUID VOLUMES IN MULTI-SCALE SPACES OF SHALE OIL RESERVOIRS

(71) Applicant: NEPU SANYA OFFSHORE OIL&GAS RESEARCH INSTITUTE, Sanya City, HI (US)

(72) Inventors: Xiaofeng ZHOU, Daqing City (CN); Jianguang WEI, Daqing City (CN); Siyu XIAO, Daqing City (CN); Xiaofei FU, Daqing City (CN); Yanping CHU, Daqing City (CN); Jiangtao LI, Daqing City (CN); Ying YANG, Daqing City (CN); Anlun WANG, Daqing City (CN)

(21) Appl. No.: 19/053,298

(22) Filed: Feb. 13, 2025

(30) Foreign Application Priority Data
Feb. 19, 2024 (CN) 202410181698.5

(51) Int. Cl. G01N 24/08; G01N 1/28; G01N 5/04; G01R 33/50

(52) U.S. Cl. CPC G01N 24/081; G01N 1/286; G01N 5/04; G01R 33/50; G01N 2001/2873

(57) ABSTRACT

Provided is a method for determining huff and puff fluid volumes in multi-scale spaces of shale oil reservoirs, including the following steps: rock sample pretreatment; porosity stress sensitivity testing; high pressure hg injection testing and nuclear magnetic resonance testing benchmarking; online nuclear magnetic resonance testing; data processing and analysis. Firstly, a changing law of multi-scale spaces of shale oil reservoirs with an effective stress is characterized through a pore stress sensitivity measurement and online nuclear magnetic resonance measurement combined experiment, and then the huff and puff fluid volumes of multi-scale spaces of shale oil reservoirs under a condition of a certain stimulated reservoir volume are calculated. A usage amount of a fracturing fluid for a fracturing horizontal well in the shale oil reservoir is determined from the perspective of giving full play to the imbibition replacement role of micro-nano pores.

### CROSS REFERENCE TO RELATED APPLICATION

This patent application claims the benefit and priority of Chinese Patent Application No. 202410181698.5, filed with the China National Intellectual Property Administration on Feb. 19, 2024, the disclosure of which is incorporated by reference herein in its entirety as part of the present application.

### TECHNICAL FIELD

The present disclosure relates to the field of exploration and development of unconventional shale oil and gas reservoirs, and in particular, to a method for determining huff and puff fluid volumes in multi-scale spaces of shale oil reservoirs.

### BACKGROUND

As the exploration and development techniques for oil and gas resources have become increasingly mature in China, the development of oil and gas reservoirs gradually changes towards the development of unconventional oil and gas resources. Unconventional oil and gas resources such as shale oil exhibit a huge development potential and are gradually becoming important strategic resources in China. Large-scale volume hydraulic fracturing of a horizontal well is a main technical means for reservoir stimulation to improve production. The scale of the volume hydraulic fracturing is closely related to the amount of fracturing fluid used and the amount of sand added. The amount of the fracturing fluid used is one of important parameters of the hydraulic fracturing solution design.

At present, the usage amount of a hydraulic fracturing fluid is mainly determined by methods such as theoretical calculation, numerical simulation, and data statistical analysis. The theoretical calculation is a hydraulic fracturing scale design method proposed based on a proppant index for the purpose of maximizing the well production performance. By this method, the optimal geometric dimensions of hydraulic fractures are deduced by establishing a matching relationship between a dimensionless optimal flow conductivity and a dimensionless maximum production index, thereby estimating the usage amount of the hydraulic fracturing fluid. The numerical simulation method is to establish a hydraulic fracture model of an oil and gas reservoir under given reservoir geological and development engineering conditions based on the material balance principle. Under specific initial conditions and boundary conditions, relationships of the usage amount of a fracturing fluid with parameters such as a fluid pressure drop, fracture geometry parameters (length, width, and height), and an injection rate are simulated, and then the optimization design of a fracturing solution is carried out. By means of the numerical simulation, related parameters are designed and adjusted in terms of the length, the width, and the height of the hydraulic fractures, thereby determining the usage amount of the hydraulic fracturing fluid. The data statistical analysis method is to determine key main fracturing control parameters affecting the well production performance by collecting fracturing and trial production data of a well that has been put into production, and screening and processing the collected data. By the statistical analysis of the fracturing parameters of the well that has been put into production, the optimization design of the hydraulic fracturing scale of a new well is carried out.

The above three methods for determining the usage amount of the fracturing fluid cannot be effectively applied to the optimization design of hydraulic fracturing of the shale oil reservoir for the following main reasons: (1) the three methods do not involve corresponding indoor physical modeling experiments, leading to lack of experimental data support for the given results of the usage amount of the fracturing fluid; (2) the calculation of the usage amount of the fracturing fluid does not take an influence of a change in effective stress of reservoir on huff and puff fluid volumes of multi-scale spaces of shale oil reservoirs in the fracturing construction process into account; and (3) a lot of micro-nano pores are developed in the shale oil reservoir matrix, and the imbibition replacement role of the micro-nano pores is to increase the main control factor of the oil production of the shale oil reservoir. The three methods do not take the influence of the imbibition replacement effect of the micro-nano pores on the usage amount of the fracturing fluid into account.

The 3 disadvantages of the above methods result in a large number of inefficient and ineffective fracturing wells due to the usage amount of the fracturing fluid not matching the geological conditions of the shale oil reservoir in its actual development process. Therefore, it is necessary to conduct research on the usage amount of the fracturing fluid for the shale oil reservoir and establish a new method for determining huff and puff fluid volumes of multi-scale spaces of shale oil reservoirs in a multistage fracturing horizontal well for scientifically guiding the design of a shale oil reservoir fracturing.

### SUMMARY

In order to solve the problems in the background, the present disclosure provides a new method for determining huff and puff fluid volumes of multi-scale spaces of shale oil reservoirs in a multistage fracturing horizontal well. Firstly, a changing law of multi-scale spaces of shale oil reservoirs with an effective stress is characterized through a pore stress sensitivity measurement and online nuclear magnetic resonance measurement combined experiment, and then the huff and puff fluid volumes of multi-scale spaces of shale oil reservoirs under a condition of a certain stimulated reservoir volume are calculated. A usage amount of a fracturing fluid for a fracturing horizontal well in the shale oil reservoir is determined from the perspective of giving full play to the imbibition replacement role of micro-nano pores. The method for determining huff and puff fluid volumes of multi-scale spaces of shale oil reservoirs proposed in the present disclosure provides a fire-new scientific means for determining the usage amount of the fracturing fluid for the multistage fracturing horizontal well in the shale oil reservoir. The patent research results have important scientific guiding significance for the optimization design of fracturing solutions for unconventional shale oil and gas reservoirs.

The present disclosure provides the following technical solutions: a method for determining huff and puff fluid volumes in multi-scale spaces of shale oil reservoirs includes the following steps:

### (1) Rock Sample Pretreatment

1) rock sample selection: selecting 5 standard plunger rock samples of a shale oil reservoir from a same coring interval of a target sub-area, which are marked as shale core 1 #, shale core 2 #, shale core 3 #, shale core 4 #, and shale core 5 #, where the shale core 1 # and the shale core 2 # are used for determining a drying temperature and a drying time, and the shale core 3 # for porosity stress sensitivity testing, the shale core 4 # for determining a time-to-space conversion coefficient, and the shale core 5 # for online nuclear magnetic resonance testing; and it is to be noted that after selecting and determining the shale core 4 #, averagely cutting the shale core 4 # into two shale cores by wire cutting, where the shale core 4 #-1 is used for high pressure hg injection testing, and the shale core 4 #-2 is used for nuclear magnetic resonance testing with saturated simulated formation water;
2) rock sample porosity measurement under overburden pressure
measuring porosities of the shale cores 1 #, 2 #, 3 #, 4 #, and 5 # under an overburden pressure using French VINCE porosity measurement meter, where when an average relative error of porosity measurement results of the rock samples is less than 2%, the rock samples selected from the same coring interval have a similar reservoir space feature for carrying out a subsequent experiment; and if the average relative error is greater than 2%, rock samples need to be reselected until the porosity meets a set error requirement;
3) determination of drying temperature and time of rock sample
(a) according to a principle of sequentially increasing by 20° C., setting 8 different drying temperatures 30° C., 50° C., 70° C., 90° C., 110° C., 130° C., 150° C., and 170° C.;
(b) drying the shale core 1 # at the 8 different drying temperatures for 8 hours, and measuring corresponding rock sample masses m₁, m₂, m₃, m₄, m₅, m₆, m₇, and m₈ of the shale core 1 # at the 8 different drying temperatures;
(c) plotting a changing curve of the mass of the shale core 1 # with the drying temperatures, where the changing curve of the rock sample mass with the drying temperatures has an inflection point when a mobile fluid in the shale core 1 # is removed completely, and a temperature corresponding to the inflection point is a pretreatment drying temperature Tₒ for the rock samples;
(d) setting 12 different drying times 1 h, 3 h, 5 h, 8 h, 12 h, 24 h, 36 h, 48 h, 72 h, 96 h, 120 h, and 144 h;
(e) drying the shale core 2 # at the pretreatment drying temperature Tₒ according to the 12 different drying times, and measuring corresponding rock sample masses m′₁, m′₂, m′₃, m′₄, m′₅, m′₆, m′₇, m′₈, m′₉, m′₁₀, m′₁₁, and m′₁₂ of the shale core at the 12 different drying times; and
(f) plotting a changing curve of the mass of the shale core 2 # with the drying times, where the rock sample mass does not change with the drying times when the mobile fluid in the shale core is removed completely, and at this time, the corresponding time is a pretreatment drying time t₀;

### (2) Porosity Stress Sensitivity Testing

measuring porosities of the shale core 3 # under different net pressures using French VINCE overburden-pressure porosity and permeability meter, which includes the following specific steps:
1) treating the shale core 3 # under the conditions of the pretreatment drying temperature Tₒ and the pretreatment drying time t₀;
2) measuring a length, a diameter, and a weight of the shale core 3 #;
3) setting net pressure points for the porosity stress sensitivity testing based on a pressure coefficient change feature in fracturing energy increasing, exploitation and production, and later energy supplementing processes of the shale oil reservoir of the target sub-area, where in order to guarantee that net pressure testing points match the three processes, a starting pressure of the net pressure testing points is 2.5 MPa, with an interval of the net pressure testing points being 2.5 or 5 MPa while guaranteeing that a net pressure testing point matches a formation pressure;
4) carrying out the porosity stress sensitivity testing matching the fracturing energy increasing, exploitation and production, and later energy supplementing processes according to the set net pressure testing points; and
5) plotting a changing curve of the porosity with the net pressure in the fracturing energy increasing, exploitation and production, and later energy supplementing processes;

### (3) High Pressure Hg Injection Testing and Nuclear Magnetic Resonance Testing Benchmarking

1) treating the shale core 4 # under the conditions of the pretreatment drying temperature Tₒ and the pretreatment drying time t₀;
2) measuring a length, a diameter, and a weight of the shale core 4 #;
3) averagely cutting the shale core into two shale cores by wire cutting, and numbering the two shale cores as shale core 4 #-1 and shale core 4 #-2;
4) carrying out the high pressure hg injection testing on the shale core 4 #-1 using PoreMaster-60 automatic mercury porosimeter, plotting a changing curve of a pore distribution frequency with a pore radius under a condition of semilogarithmic coordinates, and determining a pore distribution characteristic of the shale core 4 #-1; and
5) carrying out nuclear magnetic resonance T₂ spectrum testing on the shale core 4 #-2 using a nuclear magnetic resonance spectrometer after saturation with simulated formation water under formation temperature and pressure conditions, and plotting a changing curve of a number of nuclear magnetic signals with a relaxation time T₂ under the condition of semilogarithmic coordinates;

### (4) Online Nuclear Magnetic Resonance Testing

measuring porosities of the shale core 5 # under different net pressures using an online nuclear magnetic resonance spectrometer, which includes the following specific steps:
1) treating the shale core 5 # under the conditions of the pretreatment drying temperature Tₒ and the pretreatment drying time t₀;
2) measuring a length, a diameter, and a weight of the shale core 5 #;
3) carrying out nuclear magnetic resonance testing on the shale core 5 # after drying using the online nuclear magnetic resonance spectrometer;
4) putting the shale core 5 # into a core holder, loading a confining pressure of 2 MPa by using a hand pump, and then vacuumizing the rock sample by using a vacuumizing pretreatment system for not less than 48 h;
5) preparing experimental simulated formation water and putting the experimental simulated formation water in a piston container for later use;
6) injecting the simulated formation water in the piston container into the shale core 5 # under a constant pressure using the hand pump; progressively increasing an injection pressure and a confining pressure stepwise in a saturation process and keeping a difference between the confining pressure and the injection pressure at a constant value, and recording an initial reading V₁ of a ruler of the hand pump; when the injection pressure reaches the formation pressure, stopping the saturation process, and recording a reading V₂ of the ruler of the hand pump; keeping the confining pressure consistent with an overlying formation pressure, and regulating the injection pressure by the hand pump, where the saturation process of the rock sample is completed in an incubator at a temperature consistent with the formation temperature, with a total saturation time being not less than 48 hours;
7) carrying out nuclear magnetic resonance T₂ spectrum testing on the shale core 5 # using the online nuclear magnetic resonance spectrometer after saturation with the simulated formation water under the formation temperature and pressure conditions;
8) keeping a confining pressure of the core holder consistent with a value of the overlying formation pressure, injecting the simulated formation water into the shale core 5 # using the hand pump for increasing the injection pressure and simulating the fracturing energy increasing process of the actual shale oil reservoir; and when a value of the injection pressure reaches a set pressure coefficient value, stopping the injection process and recording a reading V₃ of the ruler of the hand pump;
9) carrying out nuclear magnetic resonance T₂ spectrum testing on the shale core 5 # using the online nuclear magnetic resonance spectrometer under a condition of completing the simulated fracturing energy increasing for the shale oil reservoir;
10) keeping the confining pressure of the core holder consistent with the value of the overlying formation pressure, reversely turning the hand pump to extract the simulated formation water from the shale core 5 # for reducing the injection pressure and simulating the exploitation and production process of the actual shale oil reservoir; and when the value of the injection pressure reaches the set pressure coefficient value, stopping the extraction process and recording a reading V₄ of the ruler of the hand pump;
11) carrying out nuclear magnetic resonance T₂ testing on the shale core 5 # using the online nuclear magnetic resonance spectrometer under a condition of completing the simulated exploitation and production of the shale oil reservoir;
12) keeping the confining pressure of the core holder consistent with the value of the overlying formation pressure, injecting the simulated formation water into the shale core 5 # using the hand pump for increasing the injection pressure and simulating the later energy supplementing process of the actual shale oil reservoir; and when the value of the injection pressure reaches the set pressure coefficient value, stopping the injection process and recording a reading V₅ of the ruler of the hand pump; and
13) carrying out nuclear magnetic resonance T₂ spectrum testing on the shale core 5 # using the online nuclear magnetic resonance spectrometer under a condition of completing the simulated later energy supplementing for the shale oil reservoir;

### (5) Data Processing and Analysis

1) calculating a time-to-space conversion coefficient for a nuclear magnetic resonance relaxation time T₂ and a pore size;
2) establishing a calibration relationship of a number of nuclear magnetic resonance T₂ spectrum signals to a shale porosity with simulated formation water;
3) determining a total huff and puff fluid volume of reservoir spaces in the shale oil reservoir;
4) determining huff and puff fluid volumes of multi-scale spaces of shale oil reservoirs; and
5) determining a total huff and puff fluid volume of the shale oil reservoir under a condition of any given pressure coefficient.

In the above solution, 1) in step (5) may include the following steps:
(a) extracting the high pressure hg injection testing data, namely pore radius and pore distribution frequency data, of the shale core 4 #-1, and plotting the changing curve of the pore distribution frequency with the pore radius under the condition of semilogarithmic coordinates;
(b) extracting the data of the nuclear magnetic resonance relaxation time T₂ and the number of nuclear magnetic signals of the shale core 4 #-2 after saturation with the simulated formation water under the formation temperature and pressure conditions, and plotting the changing curve of the number of nuclear magnetic signals with the relaxation time T₂ under the condition of semilogarithmic coordinates;
(c) integrating the curve data of steps (a) and (b) in a same coordinate system, and establishing a time-to-space conversion curve of the nuclear magnetic resonance relaxation time T₂ and a high pressure hg injection pore radius, where an X-axis bottom coordinate represents the pore radius and a Y-axis principal coordinate represents the pore distribution frequency; an X-axis top coordinate represents the relaxation time T₂ and a Y-axis auxiliary coordinate represents the number of nuclear magnetic signals; and
(d) calculating the time-to-space conversion coefficient starting from a relaxation time corresponding to a second peak because a first peak of the nuclear magnetic resonance T₂ spectrum after the shale core sample is saturated with the simulated formation water represents organic matter signal display, and recording the values of the nuclear magnetic resonance relaxation time T₂ᵢ and the pore radius rᵢ when nuclear magnetic signal peaks correspond to pore distribution frequency peaks of high pressure hg injection one to one; and calculating the time-to-space conversion coefficient for the value of the nuclear magnetic resonance relaxation time T₂ and the pore size of the shale core sample:

$${k}_{ts} = \frac{{k}_{ts 1} + {k}_{ts 2} + {k}_{tsi} + … + {k}_{tsn}}{n} ; \qquad ( 1 )$$

where kₜₛ represents the time-to-space conversion coefficient for the nuclear magnetic resonance relaxation time T₂ and the pore size, nn/ms; kₜₛᵢ represents the time-to-space conversion coefficient for the nuclear magnetic resonance relaxation time T₂ and the pore size under a condition of an ith corresponding peak, nm/ms; and n represents a number of nuclear magnetic signals and corresponding peaks of the pore distribution frequency of high pressure hg injection.

In the above solution, 2) in step (5) may include the following steps:
(a) based on a fluid volume injected by the hand pump in step (4), calculating, using a volumetric method, porosities of the shale core 5 # saturated with the simulated formation water under the formation temperature and pressure, fracturing energy increasing, exploitation and production, and later energy supplementing conditions, with calculation formulas being as follows:

$${ϕ}_{w , res} = ( {V}_{2} - {V}_{1} ) / ( \frac{π {d}^{2} L}{4} ) \times 100 \% = \frac{4 ( {V}_{2} - {V}_{1} )}{π {d}^{2} L} \times 100 \% \qquad ( 2 )$$

$${ϕ}_{w , frac} = ( {V}_{3} - {V}_{1} ) / ( \frac{π {d}^{2} L}{4} ) \times 100 \% = \frac{4 ( {V}_{3} - {V}_{1} )}{π {d}^{2} L} \times 1 \; 00 \% \qquad ( 3 )$$

$${ϕ}_{w , prod} = ( {V}_{4} - {V}_{1} ) / ( \frac{π {d}^{2} L}{4} ) \times 100 \% = \frac{4 ( {V}_{4} - {V}_{1} )}{π {d}^{2} L} \times 1 \; 00 \% \qquad ( 4 )$$

$${ϕ}_{w , sup} = ( {V}_{5} - {V}_{1} ) / ( \frac{π {d}^{2} L}{4} ) \times 100 \% = \frac{4 ( {V}_{5} - {V}_{1} )}{π {d}^{2} L} \times 100 \% \qquad ( 5 )$$

where ϕ_{w,res} represents a measured porosity with the saturated simulated formation water under the formation temperature and pressure conditions, %; V₁ represents the initial reading of the ruler of the hand pump, mL; V₂ represents a reading of the ruler of the hand pump when the injection pressure reaches the formation pressure, mL; ϕ_{w,frac} represents a measured porosity with the saturated simulated formation water under the fracturing energy increasing condition, %; V₃ represents a reading of the ruler of the hand pump when the injection pressure reaches a set pressure coefficient value for fracturing energy increasing, mL; ϕ_{w,prod} represents a measured porosity with the saturated simulated formation water under the exploitation and production condition, %; V₄ represents a reading of the ruler of the hand pump when the injection pressure reaches a set pressure coefficient value for exploitation and production, mL; ϕ_{w,sup} represents a measured porosity with the saturated simulated formation water under the later energy supplementing condition, %; V₅ represents a reading of the ruler of the hand pump when the injection pressure reaches a set pressure coefficient value for later energy supplementing, mL; d represents a rock sample diameter, cm; and L represents a rock sample length, cm; and
(b) based on the nuclear magnetic resonance T₂ spectrum signals after saturation with the simulated formation water in step (4), converting T₂ spectrum signal components of the shale after saturation with the simulated formation water under the formation temperature and pressure, fracturing energy increasing, exploitation and production, and later energy supplementing conditions to porosity components according to formulas (6), (7), (8), and (9):

$${ϕ}_{NMR , w , res} {\vert}_{{T}_{2}} = \frac{{S}_{w , res} {ϕ}_{w , res}}{{S}_{a c , w , res} - {S}_{a c , d}} \times 100 \% \qquad ( 6 )$$

$${ϕ}_{NMR , w , frac} {\vert}_{{T}_{2}} = \frac{{S}_{w , frac} {ϕ}_{w , frac}}{{S}_{a c , w , frac} - {S}_{a c , d}} \times 1 \; 00 \% \qquad ( 7 )$$

$${ϕ}_{NMR , w , prod} {\vert}_{{T}_{2}} = \frac{{S}_{w , prod} {ϕ}_{w , prod}}{{S}_{a c , w , prod} - {S}_{a c , d}} \times 1 \; 00 \% \qquad ( 8 )$$

$${ϕ}_{NMR , w , sup} {\vert}_{{T}_{2}} = \frac{{S}_{w , sup} {ϕ}_{w , sup}}{{S}_{a c , w , sup} - {S}_{a c , d}} \times 100 \% \qquad ( 9 )$$

where ϕ_{NMR,w,res}|_{T2} represents a porosity component after saturation with the simulated formation water under the formation temperature and pressure conditions, %; S_{w,res} represents a nuclear magnetic signal component after saturation with the simulated formation water under the formation temperature and pressure conditions, PU; S_{ac,w,res} represents an accumulated number of nuclear magnetic signals after saturation with the simulated formation water under the formation temperature and pressure conditions, PU; ϕ_{NMR,w,frac}|_{T2} represents a porosity component after saturation with the simulated formation water under the fracturing energy increasing condition, %; S_{w,frac} represents a nuclear magnetic signal component after saturation with the simulated formation water under the fracturing energy increasing condition, PU; S_{ac,w,frac} represents an accumulated number of nuclear magnetic signals after saturation with the simulated formation water under the fracturing energy increasing condition, PU; ϕ_{NMR,w,prod}|_{T2} represents a porosity component after saturation with the simulated formation water under the exploitation and production condition, %; S_{w,prod} represents a nuclear magnetic signal component after saturation with the simulated formation water under the exploitation and production condition, PU; S_{ac,w,prod} represents an accumulated number of nuclear magnetic signals after saturation with the simulated formation water under the exploitation and production condition, PU; ϕ_{NMR,w,sup}|_{T2} represents a porosity component after saturation with the simulated formation water under the later energy supplementing condition, %; S_{w,sup} represents a nuclear magnetic signal component after saturation with the simulated formation water under the later energy supplementing condition, PU; S_{ac,w,sup} represents an accumulated number of nuclear magnetic signals after saturation with the simulated formation water under the later energy supplementing condition, PU; and S_{ac,d} represents an accumulated number of nuclear magnetic signals after drying the shale core 5 #, PU.

In the above solution, 3) in step (5) may include the following steps:
(a) based on the porosity components calculated by formula (6) to formula (9), plotting changing relationship curves of the porosity components and accumulated values of the porosity components of the shale saturated with the simulated formation water under the formation temperature and pressure, fracturing energy increasing, exploitation and production, and later energy supplementing conditions with the relaxation time T₂, respectively;
(b) based on the time-to-space conversion coefficient kₜₛ for the nuclear magnetic resonance relaxation time T₂ and the pore size determined by formula (1), calculating pore diameters corresponding to different relaxation times T₂ under the formation temperature and pressure, fracturing energy increasing, exploitation and production, and later energy supplementing conditions, and plotting changing relationship curves of the porosity components and accumulated values of the porosity components of the shale saturated with the simulated formation water with the relaxation time T₂ and the pore diameter in the same coordinate system, where an X-axis bottom coordinate represents the relaxation time T₂ and a Y-axis principal coordinate represents the porosity component; an X-axis top coordinate represents the pore diameter and a Y-axis auxiliary coordinate represents the accumulated value of the porosity components; and
(c) based on the changing relationship curves of the porosity components and accumulated values of the porosity components of the shale saturated with the simulated formation water with the relaxation time T₂ and the pore diameter obtained in the previous step, calculating a total huff and puff fluid volume of a multistage fracturing horizontal well in the shale oil reservoir from the fracturing energy increasing to exploitation and production processes, as shown in the following formula:

$${V}_{t} = V ( {ϕ}_{NMR , w , frac}^{t} - {ϕ}_{NMR , w , prod}^{t} ) \qquad ( 10 )$$

where Vₜ represents the total huff and puff fluid volume of the multistage fracturing horizontal well in the shale oil reservoir from the fracturing energy increasing to exploitation and production processes, 10⁴ m³; V represents a stimulated reservoir volume (SRV) of the multistage fracturing horizontal well in the shale oil reservoir, 10⁴ m³; ϕ_{NMR,w,frac}^{t} represents an accumulated value of the porosity components after saturation with the simulated formation water under the fracturing energy increasing condition, %; and ϕ_{NMR,w,prod}^{t} represents an accumulated value of the porosity components after saturation with the simulated formation water under the exploitation and production condition, %.
4) The huff and puff fluid volumes of multi-scale spaces of shale oil reservoirs are determined.

In the above solution, 4) in step (5) may include the following steps.

The present disclosure proposes two methods of dividing the multi-scale spaces of shale oil reservoirs: (1) when the division of a peak interval of the nuclear magnetic resonance T₂ spectrum signals is not obvious, solution [symbol] is adopted, i.e., a division standard for pores of different sizes is as follows: micropores with a pore radius<0.01 μm, minipores with a pore radius of 0.01-0.1 μm, mesopores with a pore radius of 0.1-1.0 μm, and macropores with a pore radius>1.0 μm; (2) when the division of a peak interval of the nuclear magnetic resonance T₂ spectrum signals is obvious, the pores of different sizes are determined according to the peak interval of the T₂ spectrum signals, and then the dividing values of micropores, minipores, mesopores, and macropores are determined.

With 0.01 μm, 0.1 μm, and 1 μm as boundaries of micropores, minipores, mesopores, and macropores, calculation processes of the huff and puff fluid volumes of the multi-scale spaces of shale oil reservoirs are explained, which includes the following steps:
(a) based on the time-to-space conversion coefficient kₜₛ, calculating dividing values of the relaxation time T₂ corresponding to divided radii of micropores, minipores, mesopores, and macropores, namely the values T_{2,10nm}, T_{2,100nm}, and T_{2,1000nm} of the relaxation time T₂ corresponding to 10 nm, 100 nm, and 1000 nm;
(b) based on the values T_{2,10nm}, T_{2,100nm}, and T_{2,1000nm}, calculating porosities ϕ^{mic}_{NMR,w,frac}, ϕ^{min}_{NMR,w,frac}, ϕ^{mes}_{NMR,w,frac}, and ϕ^{mac}_{NMR,w,frac} of micropores, minipores, mesopores, and macropores after saturation with the simulated formation water under the fracturing energy increasing condition and porosities ϕ^{mic}_{NMR,w,prod}, ϕ^{min}_{NMR,w,prod}, ϕ^{mes}_{NMR,w,prod}, and ϕ^{mac}_{NMR,w,prod} of micropores, minipores, mesopores, and macropores after saturation with the simulated formation water under the exploitation and production condition by formulas (11)-(18);

$${ϕ}_{NMR , w , frac}^{mic} = \frac{{S}_{w , frac} {\vert}_{{T}_{2 , 10 n m}} \times {ϕ}_{w , frac}}{{S}_{a c , w , frac} - {S}_{a c , d}} \qquad ( 11 )$$

$${ϕ}_{NMR , w , frac}^{m i n} = \frac{( {S}_{w , frac} {\vert}_{{T}_{2 , 100 n m}} - {S}_{w , frac} {\vert}_{{T}_{2 , 10 n m}} ) \times {ϕ}_{w , frac}}{{S}_{a c , w , frac} - {S}_{a c , d}} \qquad ( 12 )$$

$${ϕ}_{NMR , w , frac}^{mes} = \frac{( {S}_{w , frac} {\vert}_{{T}_{2 , 1000 n m}} - {S}_{w , frac} {\vert}_{{T}_{2 , 100 n m}} ) \times {ϕ}_{w , frac}}{{S}_{a c , w , frac} - {S}_{a c , d}} \qquad ( 13 )$$

$${ϕ}_{NMR , w , frac}^{mac} = \frac{( {S}_{a c , w , frac} - {S}_{w , frac} {\vert}_{{T}_{2 , 1000 n m}} ) \times {ϕ}_{w , frac}}{{S}_{a c , w , frac} - {S}_{a c , d}} \qquad ( 14 )$$

$${ϕ}_{NMR , w , prod}^{mic} = \frac{{S}_{w , prod} {\vert}_{{T}_{2 , 10 n m}} \times {ϕ}_{w , prod}}{{S}_{a c , w , prod} - {S}_{a c , d}} \qquad ( 15 )$$

$${ϕ}_{NMR , w , prod}^{m i n} = \frac{( {S}_{w , prod} {\vert}_{{T}_{2 , 100 n m}} - {S}_{w , prod} {\vert}_{{T}_{2 , 10 n m}} ) \times {ϕ}_{w , prod}}{{S}_{a c , w , prod} - {S}_{a c , d}} \qquad ( 16 )$$

$${ϕ}_{NMR , w , prod}^{mes} = \frac{( {S}_{w , prod} {\vert}_{{T}_{2 , 1000 n m}} - {S}_{w , prod} {\vert}_{{T}_{2 , 100 n m}} ) \times {ϕ}_{w , prod}}{{S}_{a c , w , prod} - {S}_{a c , d}} \qquad ( 17 )$$

$${ϕ}_{NMR , w , prod}^{mac} = \frac{( {S}_{a c , w , prod} - {S}_{w , prod} {\vert}_{{T}_{2 , 1000 n m}} ) \times {ϕ}_{w , prod}}{{S}_{a c , w , prod} - {S}_{a c , d}} \qquad ( 18 )$$

where S_{w,frac}|_{T2,10nm} represents an accumulated value of the nuclear magnetic signals of micropores after saturation with the simulated formation water under the fracturing energy increasing condition, PU; S_{w,frac}|_{T2,100nm} represents an accumulated value of the nuclear magnetic signals of minipores after saturation with the simulated formation water under the fracturing energy increasing condition, PU; S_{w,frac}|_{T2,1000nm} represents an accumulated value of the nuclear magnetic signals of mesopores after saturation with the simulated formation water under the fracturing energy increasing condition, PU; S_{w,prod}|_{T2,10nm} represents an accumulated value of the nuclear magnetic signals of micropores after saturation with the simulated formation water under the exploitation and production condition, PU; S_{w,prod}|_{T2,100nm} represents an accumulated value of the nuclear magnetic signals of minipores after saturation with the simulated formation water under the exploitation and production condition, PU; and S_{w,prod}|_{T2,1000nm} represents an accumulated value of the nuclear magnetic signals of mesopores after saturation with the simulated formation water under the exploitation and production condition, PU; and
(c) based on variations of the porosities of different scales from the fracturing energy increasing to exploitation and production processes, calculating extreme huff and puff fluid volumes of the multi-scale spaces of shale oil reservoirs for the multistage fracturing horizontal well from the fracturing energy increasing to exploitation and production processes according to formula (19) to formula (22);

$${V}_{t}^{mic} = V ( {ϕ}_{NMR , w , frac}^{mic} - {ϕ}_{NMR , w , prod}^{mic} ) \qquad ( 19 )$$

$${V}_{t}^{m i n} = V ( {ϕ}_{NMR , w , frac}^{m i n} - {ϕ}_{NMR , w , prod}^{m i n} ) \qquad ( 20 )$$

$${V}_{t}^{mes} = V ( {ϕ}_{N MR , w , frac}^{mes} - {ϕ}_{NMR , w , prod}^{mes} ) \qquad ( 21 )$$

$${V}_{t}^{mac} = V ( {ϕ}_{NMR , w , frac}^{mac} - {ϕ}_{NMR , w , prod}^{mac} ) \qquad ( 22 )$$

where V^{mic}ₜ represents an extreme huff and puff fluid volume of micropores of the multistage fracturing horizontal well in the shale oil reservoir from the fracturing energy increasing to exploitation and production processes, 10⁴ m³; V^{mic}ₜ represents an extreme huff and puff fluid volume of minipores of the multistage fracturing horizontal well in the shale oil reservoir from the fracturing energy increasing to exploitation and production processes, 10⁴ m³; V^{mes}ₜ represents an extreme huff and puff fluid volume of mesopores of the multistage fracturing horizontal well in the shale oil reservoir from the fracturing energy increasing to exploitation and production processes, 10⁴ m³; and V^{mac}ₜ represents an extreme huff and puff fluid volume of macropores of the multistage fracturing horizontal well in the shale oil reservoir from the fracturing energy increasing to exploitation and production processes, 10⁴ m³.

In the above solution, 5) in step (5) may include the following steps:
by formula (23) to formula (27), calculating a conversion coefficient for an overburden-pressure porosity measured with gas and a nuclear magnetic porosity measured with water, converting a testing result of the porosity measured with gas and the stress sensitivity (see FIG. 4) under the overburden pressure condition to the nuclear magnetic porosity measured with water, and then determining the total hull and pull fluid volume in the shale oil reservoir under the condition of any given pressure coefficient in the fracturing energy increasing, exploitation and production, and later energy supplementing processes;

$${k}_{g \to w , res} = \frac{{ϕ}_{g , res}}{{ϕ}_{w , res}} \qquad ( 23 )$$

$${k}_{g \to w} = \frac{{ϕ}_{g , frac}}{{ϕ}_{w , frac}} \qquad ( 24 )$$

$${k}_{g \to w} = \frac{{ϕ}_{g , prod}}{{ϕ}_{w , prod}} \qquad ( 25 )$$

$${k}_{g \to w , sup} = \frac{{ϕ}_{g , sup}}{{ϕ}_{w , sup}} \qquad ( 26 )$$

$${\overline{k}}_{g \to w} = \frac{{k}_{g \to w , res} + {k}_{g \to w , frac} + {k}_{g \to w , prod} + {k}_{g \to w , sup}}{4} \qquad ( 27 )$$

where ϕ_{g,res} represents a porosity measured with gas under the condition of the formation pressure, %; ϕ_{g,frac} represents a porosity measured with gas under the fracturing energy increasing condition, %; ϕ_{g,prod} represents a saturated porosity measured with gas under the exploitation and production condition, %; ϕ_{g,sup} represents a porosity measured with gas under the later energy supplementing condition, %; k_{g→w,res} represents a conversion coefficient for the overburden-pressure porosity measured with gas and the nuclear magnetic porosity measured with water under the condition of the formation pressure, dimensionless; k_{g→w,frac} represents a conversion coefficient for the overburden-pressure porosity measured with gas and the nuclear magnetic porosity measured with water under the fracturing energy increasing condition, dimensionless; k_{g→w,prod} represents a conversion coefficient for the overburden-pressure porosity measured with gas and the nuclear magnetic porosity measured with water under the exploitation and production condition, dimensionless; k_{g→w,sup} represents a conversion coefficient for the overburden-pressure porosity measured with gas and the nuclear magnetic porosity measured with water under the later energy supplementing condition, dimensionless; and k̅_{g→w} represents a conversion coefficient for the overburden-pressure porosity measured with gas and the nuclear magnetic porosity measured with water under the condition of any given pressure coefficient, dimensionless; and
the total huff and puff fluid volume of the shale oil reservoir under the condition of any given pressure coefficient is calculated by formula (28):

$${V}_{t} = V ( \frac{{ϕ}_{g}}{{\overline{k}}_{g \to w}} - {ϕ}_{NMR , w , prod}^{t} ) ; \qquad ( 28 )$$

where ϕ_{g} represents a porosity measured with gas under the condition of any given pressure coefficient, %; and Vₜ the total huff and puff fluid volume of the shale oil reservoir under the condition of any given pressure coefficient, 10⁴ m³.

The present disclosure has the following beneficial effects: the present disclosure innovatively proposes the method for determining huff and puff fluid volumes in multi-scale spaces of shale oil reservoirs based on a core stress sensitivity measurement, high pressure hg injection measurement, and nuclear magnetic resonance measurement combined experiment. The present disclosure solves the problems of lack of experimental data support, not considering the effects of the effective stress and the imbibition replacement of the micro-nano pores on imbibition, and the like in determining the usage amount of the hydraulic fracturing fluid by existing methods such as theoretical calculation, numerical simulation, and data statistical analysis. In the present disclosure, firstly, a changing law of multi-scale spaces of shale oil reservoirs with an effective stress is characterized through a pore stress sensitivity measurement and online nuclear magnetic resonance measurement combined experiment, and then the huff and puff fluid volumes of multi-scale spaces of shale oil reservoirs under a condition of a certain stimulated reservoir volume are calculated. A usage amount of a fracturing fluid for a fracturing horizontal well in the shale oil reservoir is determined from the perspective of giving full play to the imbibition replacement role of micro-nano pores. The method for determining huff and puff fluid volumes of multi-scale spaces of shale oil reservoirs proposed in the present disclosure provides a fire-new scientific means for determining the usage amount of the fracturing fluid for the multistage fracturing horizontal well in the shale oil reservoir, which has important scientific guiding significance for the optimization design of fracturing solutions for unconventional shale oil and gas reservoirs.

### BRIEF DESCRIPTION OF THE DRAWINGS

FIGS. 1A-1E show images of 5 shale core samples;

FIG. 2 is a diagram illustrating a changing curve of the mass of shale core 1 # with a drying temperature;

FIG. 3 is a diagram illustrating a changing curve of the mass of shale core 2 # with a drying time;

FIG. 4 is a diagram illustrating porosity stress sensitivity measurement results of shale core 3 #;

FIG. 5 is a diagram illustrating a time-to-space conversion curve for a value of a nuclear magnetic resonance relaxation time T₂ and a pore size; and

FIG. 6 is a diagram illustrating changing relationship curves of porosity components and accumulated values of the porosity components of shale saturated with simulated formation water under different conditions with a relaxation time T₂ and a pore diameter.

### DETAILED DESCRIPTION OF THE EMBODIMENTS

The present disclosure is further described below with reference to the accompanying drawings and examples.

A method for determining huff and puff fluid volumes in multi-scale spaces of shale oil reservoirs includes the following steps.

### 1. Rock Sample Pretreatment

### 1) Rock Sample Selection

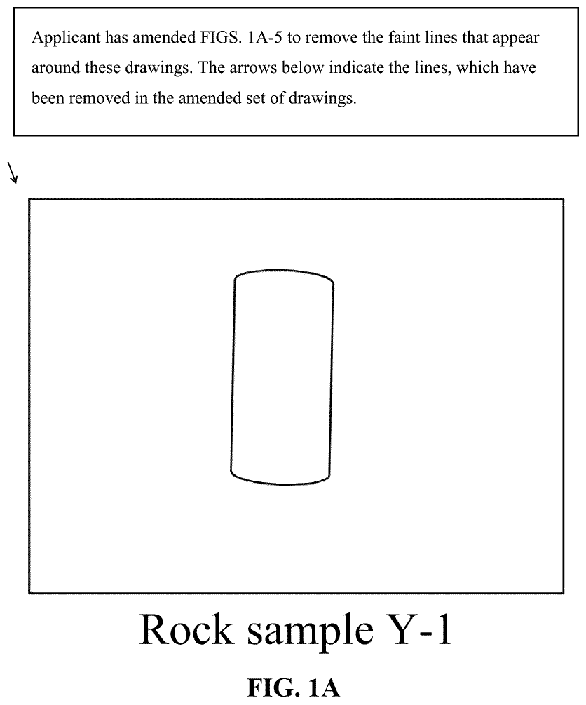

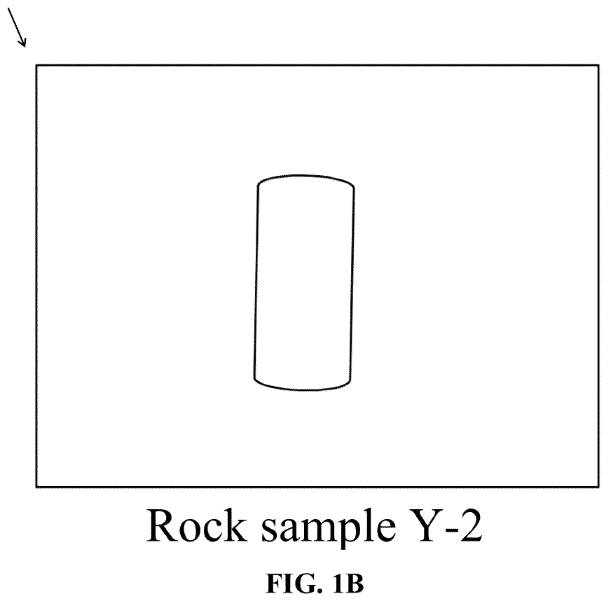

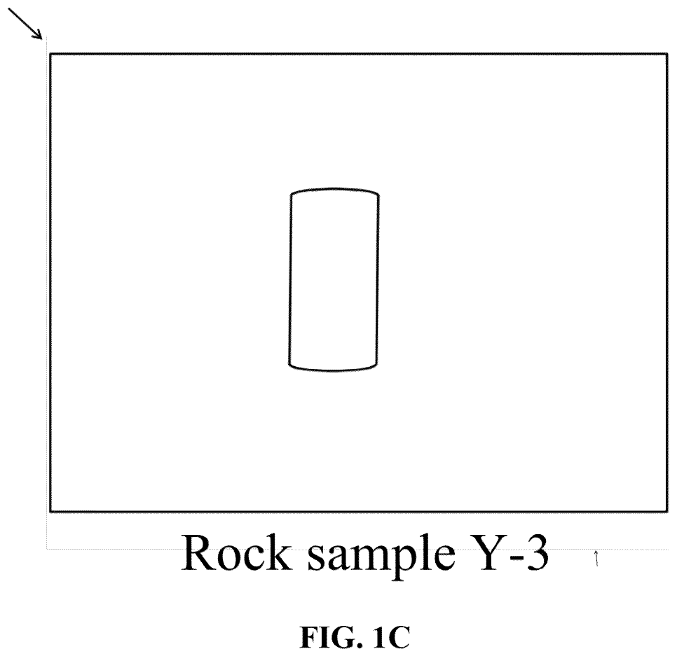

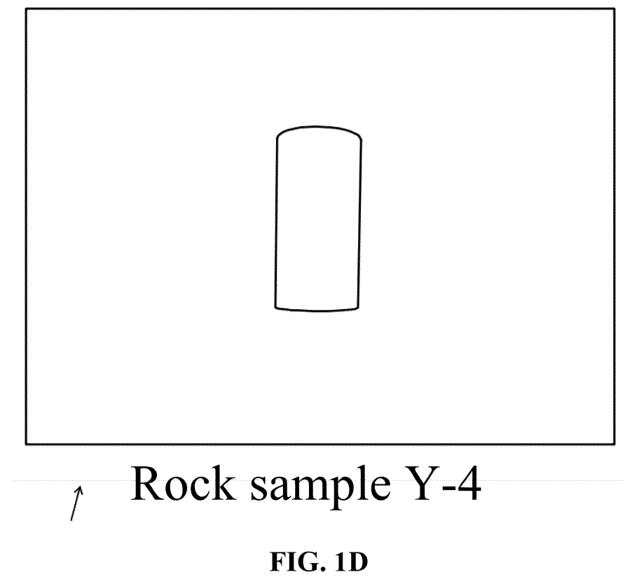

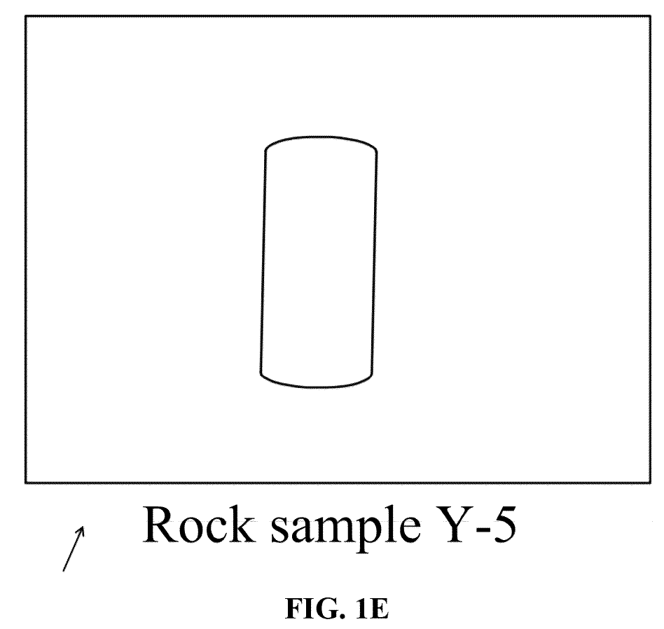

5 standard plunger rock samples are selected from the fourth member of Shahejie formation of a shale oil reservoir and marked as shale core 1 #, shale core 2 #, shale core 3 #, shale core 4 #, and shale core 5 #. The shale core 1 # is numbered as Y-1, and the shale core 2 # as Y-2, the shale core 3 # as Y-3, the shale core 4 # as Y-4, and the shale core 5 # as Y-5. The photos of the rock samples are as shown in FIGS. 1A-1E, and basic parameters of the rock samples are as shown in Table 1. The shale core 1 # and the shale core 2 # are used for determining a drying temperature and a drying time, and the shale core 3 # for porosity stress sensitivity testing, the shale core 4 # for determining a time-to-space conversion coefficient, and the shale core 5 # for online nuclear magnetic resonance testing. It needs to be noted that after the shale core 4 # is selected and determined, the shale core 4 # is averagely cut into two shale cores by wire cutting, where the shale core 4 #-1 is used for high pressure hg injection testing, and the shale core 4 #-2 is used for nuclear magnetic resonance testing with saturated water.

TABLE 1
Basic Parameters of Rock Samples

| Serial | Well | | Coring | Length | Diameter | Weight |
|---|---|---|---|---|---|---|
| Number | number | Number | Interval (m) | (cm) | (cm) | (g) |
| 1 | HC-1 | Y-1 | 2937.58 | 4.996 | 2.5 | 54.982 |
| 2 | | Y-2 | 2937.58 | 5.016 | 2.5 | 55.513 |
| 3 | | Y-3 | 2937.58 | 4.982 | 2.5 | 54.956 |
| 4 | | Y-4 | 2937.58 | 5.028 | 2.5 | 55.559 |
| 5 | | Y-5 | 2937.58 | 5.012 | 2.5 | 55.114 |

### 2) Rock Sample Porosity Measurement Under Overburden Pressure

The porosities of the shale core 1 #, the shale core 2 #, the shale core 3 #, the shale core 4 #, and the shale core 5 # under the overburden pressure (2.5 MPa) condition are measured using French VINCE porosity measurement meter, and measurement results are as shown in Table 2.

TABLE 2
Measurement Results of Porosities of Shale Cores with Gas under Overburden Pressure Condition

| Serial | Well | | Coring | Porosity | Porosity | Relative | Relative Error |
|---|---|---|---|---|---|---|---|
| Number | number | Number | Interval (m) | (%) | Mean (%) | Error (%) | Mean (%) |
| 1 | HC-1 | Y-1 | 1608.48 | 10.249 | 10.140 | 1.071 | 1.238 |
| 2 | | Y-2 | 1608.48 | 10.023 | | 1.154 | |
| 3 | | Y-3 | 1608.48 | 10.288 | | 1.459 | |
| 4 | | Y-4 | 1608.48 | 10.197 | | 0.566 | |
| 5 | | Y-5 | 1608.48 | 9.943 | | 1.943 | |

By analysis of data of Table 2, the average relative error of the measurement results of the porosities of the shale cores Y-1, Y-2, Y-3, Y-4, and Y-5 with gas under the overburden pressure condition is 1.238% (less than 2%), indicating that the rock samples selected from the same coring interval have a similar reservoir space feature carrying out a subsequent experiment.

### 3) Determination of Drying Temperature and Time of Rock Sample

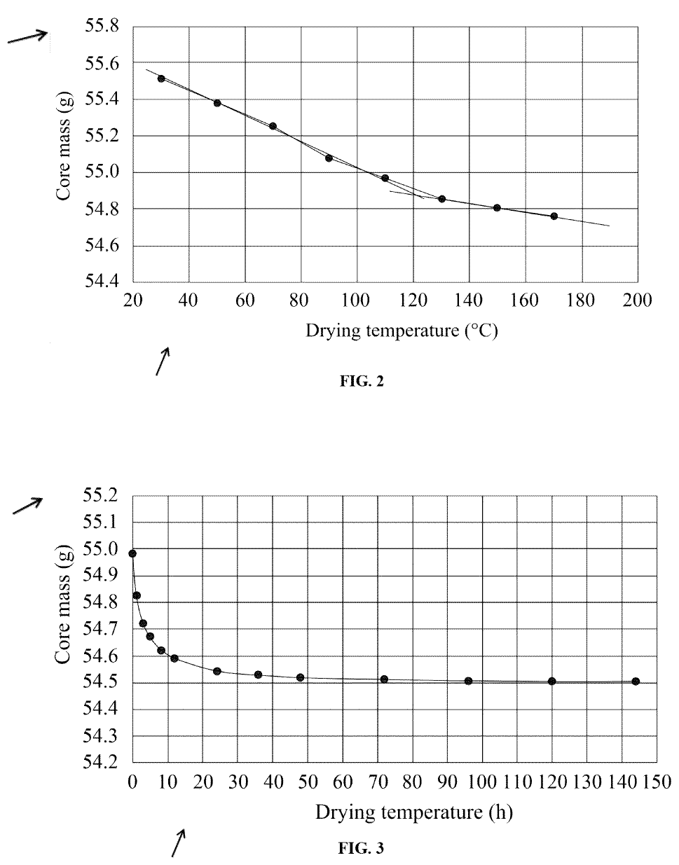

(1) According to a principle of sequentially increasing by 20° C., 8 different drying temperatures 30° C., 50° C., 70° C., 90° C., 110° C., 130° C., 150° C., and 170° C. are set.
(2) The shale core Y-1 is dried at the 8 different drying temperatures for 8 hours, and corresponding rock sample masses m₁, m₂, m₃, m₄, m₅, m₆, m₇, and m₈ of the shale core Y-1 at the 8 different drying temperatures are measured.
(3) A changing curve of the mass of the shale core Y-1 with the drying temperatures is plotted, as shown in FIG. 2. The changing curve of the rock sample mass with the drying temperatures has an inflection point when a mobile fluid in the shale core is removed completely, and a temperature corresponding to the inflection point is a pretreatment drying temperature Tₒ=110° C. for the rock samples.
(4) 12 different drying times 1 h, 3 h, 5 h, 8 h, 12 h, 24 h, 36 h, 48 h, 72 h, 96 h, 120 h, and 144 h are set.
(5) The shale core Y-2 is dried at the pretreatment drying temperature Tₒ according to the 12 different drying times, and corresponding rock sample masses m′₁, m′₂, m′₃, m′₄, m′₅, m′₆, m′₇, m′₈, m′₉, m′₁₀, m′₁₁, and m′₁₂ of the shale core at the 12 different drying times are measured.
(6) A changing curve of the mass of the shale core Y-2 with the drying times is plotted, as shown in FIG. 3. The rock sample mass does not change with the drying times when the mobile fluid in the shale core is removed completely, and at this time, the corresponding time is a pretreatment drying time t₀=48 h.

### 2. Porosity Stress Sensitivity Testing

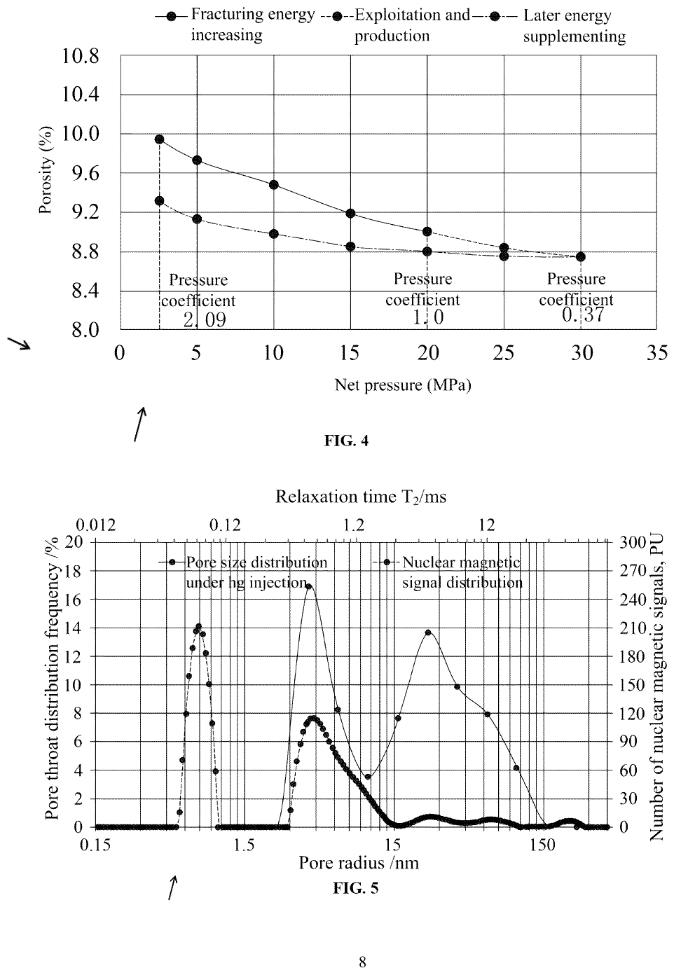

Porosities of the shale core Y-3 under different net pressures are measured using French VINCE overburden-pressure porosity and permeability meter, which includes the following specific steps.
(1) The shale core Y-3 is treated under the conditions of the pretreatment drying temperature Tₒ=1 10° C. and the pretreatment drying time t₀=48 h.
(2) A length, a diameter, and a weight (as shown in Table 1) of the shale core Y-3 are measured.
(3) Net pressure points for the porosity stress sensitivity testing are set based on a pressure coefficient change feature in fracturing energy increasing, exploitation and production, and later energy supplementing processes of the shale oil reservoir of the target sub-area. In order to guarantee that net pressure testing points can match the three processes, with reference to the measurement accuracy of the overburden-pressure porosity and permeability meter, a starting pressure of the net pressure testing points is selected to be 2.5 MPa, with an interval of the net pressure testing points being 2.5 or 5 MPa; and meanwhile, it is guaranteed that there is a net pressure testing point (20 MPa) matching a formation pressure (16 MPa) of the target sub-area. It thus can be known that the pressures corresponding to the net pressure testing points are 2.5 MPa, 5 MPa, 10 MPa, 15 MPa, 20 MPa, 25 MPa, and 30 MPa, respectively.
(4) The porosity stress sensitivity testing matching the fracturing energy increasing, exploitation and production, and later energy supplementing processes is carried out according to the set net pressure testing points.
(5) A changing curve of the porosity with the net pressure in the fracturing energy increasing, exploitation and production, and later energy supplementing processes is plotted (see FIG. 4).

High pressure hg injection testing and nuclear magnetic resonance testing benchmarking: (1) The shale core Y-4 is treated under the conditions of the pretreatment drying temperature Tₒ=110° C. and the pretreatment drying time t₀=48 h.
(2) A length, a diameter, and a weight (as shown in Table 1) of the shale core Y-4 are measured.
(3) The shale core is averagely cut into two shale cores by wire cutting, and the two shale cores are numbered as shale core 4 #-1 and shale core 4 #-2.
(4) The high pressure hg injection testing is carried out on the shale core 4 #-1 using PoreMaster-60 automatic mercury porosimeter. A changing curve of a pore distribution frequency with a pore radius (as shown by the blue curve part in FIG. 5) is plotted under a condition of semilogarithmic coordinates, and a pore distribution characteristic of the shale core 4 #-1 is determined.
(5) Nuclear magnetic resonance T₂ spectrum testing is carried out on the shale core 4 #-2 using a nuclear magnetic resonance spectrometer after saturation with simulated formation water under formation temperature and pressure conditions, and a changing curve of a number of nuclear magnetic signals with a relaxation time T₂ (as shown by the red curve part in FIG. 5) is plotted under the condition of semilogarithmic coordinates.

Online nuclear magnetic resonance testing: Porosities of the shale core Y-5 under different net pressures are measured using an online nuclear magnetic resonance spectrometer, which includes the following specific steps:
(1) The shale core Y-5 is treated under the conditions of the pretreatment drying temperature Tₒ=110° C. and the pretreatment drying time t₀=48 h.
(2) A length, a diameter, and a weight (as shown in Table 1) of the shale core Y-5 are measured.
(3) Nuclear magnetic resonance testing is carried out on the shale core Y-5 after drying using the online nuclear magnetic resonance spectrometer.
(4) The shale core Y-5 is put into a core holder; a confining pressure of 2 MPa is loaded by using a hand pump, and then the rock sample is vacuumized by using a vacuumizing pretreatment system for not less than 48 h.
(5) Experimental simulated formation water is prepared and put in a piston container for later use.
(6) The simulated formation water in the piston container is injected into the shale core Y-5 under a constant pressure using the hand pump; an injection pressure and a confining pressure are progressively increased stepwise in a saturation process and a difference between the confining pressure and the injection pressure is kept at a constant value (a difference between an overlying formation pressure and the formation pressure), and an initial reading V₁ of a ruler of the hand pump is recorded. When the injection pressure reaches the formation pressure, the saturation process is stopped, and a reading V₂ of the ruler of the hand pump is recorded. It needs to be noted that the confining pressure is kept consistent with the overlying formation pressure, and the injection pressure is regulated by the hand pump. The saturation process of the rock sample is completed in an incubator at a temperature consistent with the formation temperature, with a total saturation time being not less than 48 hours.
(7) Nuclear magnetic resonance T₂ spectrum testing is carried out on the shale core Y-5 using the online nuclear magnetic resonance spectrometer after saturation with the simulated formation water under the formation temperature and pressure conditions (as shown in FIG. 6).
(8) A confining pressure of the core holder is kept consistent with a value of the overlying formation pressure; and the simulated formation water is injected into the shale core Y-5 using the hand pump for increasing the injection pressure and simulating the fracturing energy increasing process of the actual shale oil reservoir. When a value of the injection pressure reaches a set pressure coefficient value, the injection process is stopped and a reading V₃ of the ruler of the hand pump is recorded.
(9) Nuclear magnetic resonance T₂ spectrum testing is carried out on the shale core Y-5 using the online nuclear magnetic resonance spectrometer under a condition of completing the simulated fracturing energy increasing for the shale oil reservoir (as shown in FIG. 6).
(10) The confining pressure of the core holder is kept consistent with the value of the overlying formation pressure; and the hand pump is reversely turned to extract the simulated formation water from the shale core Y-5 for reducing the injection pressure and simulating the exploitation and production process of the actual shale oil reservoir. When the value of the injection pressure reaches the set pressure coefficient value, the extraction process is stopped and a reading V₄ of the ruler of the hand pump is recorded.
(11) Nuclear magnetic resonance T₂ spectrum testing is carried out on the shale core Y-5 using the online nuclear magnetic resonance spectrometer under a condition of completing the simulated exploitation and production of the shale oil reservoir (as shown in FIG. 6).
(12) The confining pressure of the core holder is kept consistent with the value of the overlying formation pressure; and the simulated formation water is injected into the shale core Y-5 using the hand pump for increasing the injection pressure and simulating the later energy supplementing process of the actual shale oil reservoir. When the value of the injection pressure reaches the set pressure coefficient value, the injection process is stopped and a reading V₅ of the ruler of the hand pump is recorded.
(13) Nuclear magnetic resonance T₂ spectrum testing is carried out on the shale core Y-5 using the online nuclear magnetic resonance spectrometer under a condition of completing the simulated later energy supplementing for the shale oil reservoir (as shown in FIG. 6).

The hand pump readings corresponding to the volumes of simulated formation water pumped recorded in the experimental process are as shown in Table 3.

TABLE 3
Hand Pump Readings Corresponding to Volumes
of Simulated Formation Water Pumped

| V₁ (mL) | V₂ (mL) | V₃ (mL) | V₄ (mL) | V₅ (mL) |
|---|---|---|---|---|
| 2 | 3.922 | 4.093 | 3.858 | 3.957 |

5. Data processing and analysis: 1) A time-to-space conversion coefficient for a nuclear magnetic resonance relaxation time T2 and a pore size is calculated.
(1) The high pressure hg injection testing data, namely pore radius and pore distribution frequency data, of the shale core 4 #-1 is extracted, and the changing curve of the pore distribution frequency with the pore radius (as shown by the blue curve part in FIG. 5) is plotted under the condition of semilogarithmic coordinates.
(2) The data of the nuclear magnetic resonance relaxation time T₂ and the number of nuclear magnetic signals of the shale core 4 #-2 after saturation with the simulated formation water under the formation temperature and pressure conditions are extracted, and the changing curve of the number of nuclear magnetic signals with the relaxation time T₂ (as shown by the red curve part in FIG. 5) is plotted under the condition of semilogarithmic coordinates.
(3) The curve data of steps (1) and (2) are integrated in a same coordinate system, and a time-to-space conversion curve of the nuclear magnetic resonance relaxation time T₂ and a high pressure hg injection pore radius (as shown in FIG. 5) is established, where an X-axis bottom coordinate represents the pore radius and a Y-axis principal coordinate represents the pore distribution frequency; an X-axis top coordinate represents the relaxation time T₂ and a Y-axis auxiliary coordinate represents the number of nuclear magnetic signals.
(4) The time-to-space conversion coefficient is calculated starting from a relaxation time corresponding to a second peak because a first peak of the nuclear magnetic resonance T₂ spectrum after the shale core sample is saturated with the simulated formation water represents organic matter signal display, and the values of the nuclear magnetic resonance relaxation time T₂ᵢ and the pore radius rᵢ are recorded when nuclear magnetic signal peaks correspond to pore distribution frequency peaks of high pressure hg injection one to one (see Table 4). Based on the data of Table 4, the time-to-space conversion coefficient for the value of the nuclear magnetic resonance relaxation time T₂ and the pore size of the shale core sample can be calculated:

$${k}_{ts} = \frac{{k}_{ts 1} + {k}_{ts 2}}{n} = \frac{7.11 + 5.60}{2} = 6.35 nm / ms ; \qquad ( 1 )$$

where kₜₛ represents the time-to-space conversion coefficient for the nuclear magnetic resonance relaxation time T₂ and the pore size, nm/ms; kₜₛᵢ represents the time-to-space conversion coefficient for the nuclear magnetic resonance relaxation time T₂ and the pore size under a condition of an ith corresponding peak, nm/ms; and n represents a number of nuclear magnetic signals and corresponding peaks of the pore distribution frequency of high pressure hg injection.

TABLE 4
Contrast Data Table of Pore Radius and Relaxation Time T₂

| rᵢ(nm) | T₂ᵢ(ms) | kₜₛ(nm/ms) |
|---|---|---|
| 4 | 0.562 | 7.11 |
| 25 | 4.467 | 5.60 |

2) A calibration relationship of a number of nuclear magnetic resonance T2 spectrum signals to a shale porosity with simulated formation water is established.
(1) Based on a fluid volume injected by the hand pump in step 4, porosities of the shale core Y-5 saturated with the simulated formation water under the formation temperature and pressure, fracturing energy increasing, exploitation and production, and later energy supplementing conditions are calculated using a volumetric method, with calculation formulas being as follows:

$${ϕ}_{w , res} = ( {V}_{2} - {V}_{1} ) / ( \frac{π {d}^{2} L}{4} ) \times 100 \% = \frac{4 ( {V}_{2} - {V}_{1} )}{π {d}^{2} L} \times 100 \% \qquad ( 2 )$$

$${ϕ}_{w , frac} = ( {V}_{3} - {V}_{1} ) / ( \frac{π {d}^{2} L}{4} ) \times 100 \% = \frac{4 ( {V}_{3} - {V}_{1} )}{π {d}^{2} L} \times 1 \; 00 \% \qquad ( 3 )$$

$${ϕ}_{w , prod} = ( {V}_{4} - {V}_{1} ) / ( \frac{π {d}^{2} L}{4} ) \times 100 \% = \frac{4 ( {V}_{4} - {V}_{1} )}{π {d}^{2} L} \times 1 \; 00 \% \qquad ( 4 )$$

$${ϕ}_{w , sup} = ( {V}_{5} - {V}_{1} ) / ( \frac{π {d}^{2} L}{4} ) \times 100 \% = \frac{4 ( {V}_{5} - {V}_{1} )}{π {d}^{2} L} \times 1 \; 00 \% ; \qquad ( 5 )$$

where ϕ_{w,res} represents a measured porosity with the saturated simulated formation water under the formation temperature and pressure conditions, %; V₁ represents the initial reading of the ruler of the hand pump, mL; V₂ represents a reading of the ruler of the hand pump when the injection pressure reaches the formation pressure, mL; ϕ_{w,frac} represents a measured porosity with the saturated simulated formation water under the fracturing energy increasing condition, %; V₃ represents a reading of the ruler of the hand pump when the injection pressure reaches a set pressure coefficient value for fracturing energy increasing, mL; ϕ_{w,prod} represents a measured porosity with the saturated simulated formation water under the exploitation and production condition, %; V₄ represents a reading of the ruler of the hand pump when the injection pressure reaches a set pressure coefficient value for exploitation and production, mL; ϕ_{w,sup} represents a measured porosity with the saturated simulated formation water under the later energy supplementing condition, %; V₅ represents a reading of the ruler of the hand pump when the injection pressure reaches a set pressure coefficient value for later energy supplementing, mL; d represents a rock sample diameter, cm; and L represents a rock sample length, cm.

The porosities of the shale core Y-5 saturated with the simulated formation water under the formation temperature and pressure, fracturing energy increasing, exploitation and production, and later energy supplementing conditions are as shown in Table 5.

TABLE 5
Porosities of Shale Core Y-5 Saturated with Simulated
Formation Water Under Different Conditions

| ϕ_{w, res} (%) | ϕ_{w, frac} (%) | ϕ_{w, prod} (%) | ϕ_{w, sup} (%) |
|---|---|---|---|
| 7.816 | 8.512 | 7.556 | 7.958 |

(2) Based on the nuclear magnetic resonance T₂ spectrum signals after saturation with the simulated formation water in step 4, T₂ spectrum signal components of the shale after saturation with the simulated formation water under the formation temperature and pressure, fracturing energy increasing, exploitation and production, and later energy supplementing conditions are converted to porosity components according to formulas (6), (7), (8), and (9):

$${ϕ}_{NMR , w , res} {\vert}_{{T}_{2}} = \frac{{S}_{w , res} {ϕ}_{w , res}}{{S}_{a c , w , res} - {S}_{a c , d}} \times 100 \% \qquad ( 6 )$$

$${ϕ}_{NMR , w , frac} {\vert}_{{T}_{2}} = \frac{{S}_{w , frac} {ϕ}_{w , frac}}{{S}_{a c , w , frac} - {S}_{a c , d}} \times 100 \% \qquad ( 7 )$$

$${ϕ}_{NMR , w , prod} {\vert}_{{T}_{2}} = \frac{{S}_{w , prod} {ϕ}_{w , prod}}{{S}_{a c , w , prod} - {S}_{a c , d}} \times 100 \% \qquad ( 8 )$$

$${ϕ}_{NMR , w , sup} {\vert}_{{T}_{2}} = \frac{{S}_{w , sup} {ϕ}_{w , sup}}{{S}_{a c , w , sup} - {S}_{a c , d}} \times 100 \% \qquad ( 9 )$$

where ϕ_{NMR,w,res}|_{T2} represents a porosity component after saturation with the simulated formation water under the formation temperature and pressure conditions, %; S_{w,res} represents a nuclear magnetic signal component after saturation with the simulated formation water under the formation temperature and pressure conditions, PU; S_{ac,w,res} represents an accumulated number of nuclear magnetic signals after saturation with the simulated formation water under the formation temperature and pressure conditions, PU; ϕ_{NMR,w,frac}|_{T2} represents a porosity component after saturation with the simulated formation water under the fracturing energy increasing condition, %; S_{w,frac} represents a nuclear magnetic signal component after saturation with the simulated formation water under the fracturing energy increasing condition, PU; S_{ac,w,frac} represents an accumulated number of nuclear magnetic signals after saturation with the simulated formation water under the fracturing energy increasing condition, PU; ϕ_{NMR,w,prod}|_{T2} represents a porosity component after saturation with the simulated formation water under the exploitation and production condition, %; S_{w,prod} represents a nuclear magnetic signal component after saturation with the simulated formation water under the exploitation and production condition, PU; S_{ac,w,prod} represents an accumulated number of nuclear magnetic signals after saturation with the simulated formation water under the exploitation and production condition, PU; ϕ_{NMR,w,sup}|_{T2} represents a porosity component after saturation with the simulated formation water under the later energy supplementing condition, %; S_{w,sup} represents a nuclear magnetic signal component after saturation with the simulated formation water under the later energy supplementing condition, PU; S_{ac,w,sup} represents an accumulated number of nuclear magnetic signals after saturation with the simulated formation water under the later energy supplementing condition, PU; and S_{ac,d} represents an accumulated number of nuclear magnetic signals after drying the shale core Y-5, PU.

3) A total huff and puff fluid volume of reservoir spaces in the shale oil reservoir is determined.
(1) Based on the porosity components calculated by formula (6) to formula (9), changing relationship curves of the porosity components and accumulated values of the porosity components of the shale saturated with the simulated formation water under the formation temperature and pressure, fracturing energy increasing, exploitation and production, and later energy supplementing conditions with the relaxation time T₂ are calculated respectively (as shown in FIG. 6).
(2) Based on the time-to-space conversion coefficient kₜₛ for the nuclear magnetic resonance relaxation time T₂ and the pore size determined by formula (1), pore diameters corresponding to different relaxation times T₂ under the formation temperature and pressure, fracturing energy increasing, exploitation and production, and later energy supplementing conditions are calculated, and changing relationship curves of the porosity components and accumulated values of the porosity components of the shale saturated with the simulated formation water with the relaxation time T₂ and the pore diameter are plotted in the same coordinate system (as shown in FIG. 6), where an X-axis bottom coordinate represents the relaxation time T₂ and a Y-axis principal coordinate represents the porosity component; an X-axis top coordinate represents the pore diameter and a Y-axis auxiliary coordinate represents the accumulated value of the porosity components.
(3) Based on the changing relationship curves of the porosity components and accumulated values of the porosity components of the shale saturated with the simulated formation water with the relaxation time T₂ and the pore diameter obtained in the previous step, a total huff and puff fluid volume of a multistage fracturing horizontal well in the shale oil reservoir from the fracturing energy increasing to exploitation and production processes can be calculated, as shown below:

$${V}_{t} = V ( {ϕ}_{NMR , w , frac}^{t} - {ϕ}_{NMR , w , prod}^{t} ) \qquad ( 10 )$$

where Vₜ represents the total huff and puff fluid volume of the multistage fracturing horizontal well in the shale oil reservoir from the fracturing energy increasing to exploitation and production processes, 10⁴ m³; V represents a stimulated reservoir volume (SRV) of the multistage fracturing horizontal well in the shale oil reservoir, 10⁴ m³; ϕ^{t}_{NMR,w,frac} represents an accumulated value of the porosity components after saturation with the simulated formation water under the fracturing energy increasing condition, %; and ϕ^{t}_{NMR,w,prod} represents an accumulated value of the porosity components after saturation with the simulated formation water under the exploitation and production condition, %.

An average horizontal section length of the multistage fracturing horizontal well in the existing shale oil reservoir of the target sub-area is about 2000 m; an average half length of fractures is about 100 m; and an average thickness of the reservoir is about 20 m. Thus, the SRV is 800×10⁴ m³. As can be known from FIG. 6, the accumulated value ϕ^{t}_{NMR,w,frac} of the porosity components after saturation with the simulated formation water under the fracturing energy increasing condition is equal to 8.513%; the accumulated value ϕ^{t}_{NMR,w,prod} of the porosity components after saturation with the simulated formation water under the exploitation and production condition is equal to 7.557%; and the total huff and puff fluid volume of the multistage fracturing horizontal well in the shale oil reservoir from the fracturing energy increasing to exploitation and production processes is 7.648×10⁴ m³.

TABLE 6
Total Huff and Puff Fluid Volume of Multistage Fracturing Horizontal Well in Shale Oil
Reservoir of Target Sub-Area

| | | | | Porosity in | Porosity in | Total Huff |
|---|---|---|---|---|---|---|
| Horizontal | Fracture | Reservoir | | Fracturing | Exploitation | and Puff |
| Well Length | Half Length | Thickness | SRV | Energy | and | Fluid Volume |
| (m) | (m) | (m) | (10⁴ m³) | Increasing (%) | Production (%) | (10⁴ m³) |
| 2000 | 100 | 20 | 800 | 8.513 | 7.557 | 7.648 |

4) The huff and puff fluid volumes of multi-scale spaces of shale oil reservoirs are determined.

In the embodiments of the present disclosure, the pores of different sizes, i.e., dividing values of micropores, minipores, mesopores, and macropores, are determined according to the peak interval of the nuclear magnetic resonance T₂ spectrum signals, and then the huff and puff fluid volumes of the multi-scale spaces of shale oil reservoirs are determined. Specific steps are as follows.
(1) As can be known from FIG. 6, the dividing values of micropores, minipores, mesopores, and macropores are 20 nm, 100 nm, and 450 nm, respectively. Based on the time-to-space conversion coefficient kₜₛ, dividing values of the relaxation time T₂ corresponding to divided radii of micropores, minipores, mesopores, and macropores are calculated. That is, the values of the relaxation time T₂ corresponding to 20 nm, 100 nm, and 450 nm are as follows: T_{2,20nm}=1.57 ms, T_{2,100nm}=7.87 ms, and T_{2,450nm}=35.43 ms.
(2) Based on the values T_{2,20nm}, T_{2,100nm}, and T_{2,450nm}, porosities ϕ^{mic}_{NMR,w,frac}, ϕ^{min}_{NMR,w,frac}, ϕ^{mes}_{NMR,w,frac}, and ϕ^{mac}_{NMR,w,frac} of micropores, minipores, mesopores, and macropores after saturation with the simulated formation water under the fracturing energy increasing condition and porosities ϕ^{mic}_{NMR,w,prod}, ϕ^{min}_{NMR,w,prod}, ϕ^{mes}_{NMR,w,prod}, and ϕ^{mac}_{NMR,w,prod} of micropores, minipores, mesopores, and macropores after saturation with the simulated formation water under the exploitation and production condition are calculated by formulas (11)-(18), with calculation results being as shown in Table 7:

$${ϕ}_{NMR , w , frac}^{mic} = \frac{{S}_{w , frac} {\vert}_{{T}_{2 , 20 n m}} \times {ϕ}_{w , frac}}{{S}_{a c , w , frac} - {S}_{a c , d}} \qquad ( 11 )$$

$${ϕ}_{NMR , w , frac}^{m i n} = \frac{( {S}_{w , frac} {\vert}_{{T}_{2 , 100 n m}} - {S}_{w , frac} {\vert}_{{T}_{2 , 20 n m}} ) \times {ϕ}_{w , frac}}{{S}_{a c , w , frac} - {S}_{a c , d}} \qquad ( 12 )$$

$${ϕ}_{NMR , w , frac}^{mes} = \frac{( {S}_{w , frac} {\vert}_{{T}_{2 , 450 n m}} - {S}_{w , frac} {\vert}_{{T}_{2 , 100 n m}} ) \times {ϕ}_{w , frac}}{{S}_{a c , w , frac} - {S}_{a c , d}} \qquad ( 13 )$$

$${ϕ}_{NMR , w , frac}^{mac} = \frac{( {S}_{a c , w , frac} - {S}_{w , frac} {\vert}_{{T}_{2 , 450 n m}} ) \times {ϕ}_{w , frac}}{{S}_{a c , w , frac} - {S}_{a c , d}} \qquad ( 14 )$$

$${ϕ}_{NMR , w , prod}^{mic} = \frac{{S}_{w , prod} {\vert}_{{T}_{2 , 20 n m}} \times {ϕ}_{w , prod}}{{S}_{a c , w , prod} - {S}_{a c , d}} \qquad ( 15 )$$

$${ϕ}_{NMR , w , prod}^{m i n} = \frac{( {S}_{w , prod} {\vert}_{{T}_{2 , 100 n m}} - {S}_{w , prod} {\vert}_{{T}_{2 , 20 n m}} ) \times {ϕ}_{w , prod}}{{S}_{a c , w , prod} - {S}_{a c , d}} \qquad ( 16 )$$

$${ϕ}_{NMR , w , prod}^{mes} = \frac{( {S}_{w , prod} {\vert}_{{T}_{2 , 40 n m}} - {S}_{w , prod} {\vert}_{{T}_{2 , 100 n m}} ) \times {ϕ}_{w , prod}}{{S}_{a c , w , prod} - {S}_{a c , d}} \qquad ( 17 )$$

$${ϕ}_{NMR , w , prod}^{mac} = \frac{( {S}_{a c , w , prod} - {S}_{w , prod} {\vert}_{{T}_{2 , 450 n m}} ) \times {ϕ}_{w , prod}}{{S}_{a c , w , prod} - {S}_{a c , d}} \qquad ( 18 )$$

where S_{w,frac}|_{T2,20nm} represents an accumulated value of the nuclear magnetic signals of micropores after saturation with the simulated formation water under the fracturing energy increasing condition, PU; S_{w,frac}|_{T2,100nm} represents an accumulated value of the nuclear magnetic signals of minipores after saturation with the simulated formation water under the fracturing energy increasing condition, PU; S_{w,frac}|_{T2,450nm} represents an accumulated value of the nuclear magnetic signals of mesopores after saturation with the simulated formation water under the fracturing energy increasing condition, PU; S_{w,prod}|_{T2,20nm} represents an accumulated value of the nuclear magnetic signals of micropores after saturation with the simulated formation water under the exploitation and production condition, PU; S_{w,prod}|_{T2,100nm} represents an accumulated value of the nuclear magnetic signals of minipores after saturation with the simulated formation water under the exploitation and production condition, PU; and S_{w,prod}|_{T2,450nm} represents an accumulated value of the nuclear magnetic signals of mesopores after saturation with the simulated formation water under the exploitation and production condition, PU.

TABLE 7
Porosities of Different Sizes under Fracturing Energy
Increasing and Exploitation and Production Conditions

| | Porosities of Different Sizes (%) | | | | |
|---|---|---|---|---|---|
| | | | | | Total |
| Stage | Micropores | Minipores | Mesopores | Macropores | Pores |
| Fracturing | 6.509 | 0.865 | 0.534 | 0.606 | 8.513 |
| Energy | | | | | |
| Increasing | | | | | |
| Exploitation | 6.466 | 0.686 | 0.244 | 0.160 | 7.557 |
| and Production | | | | | |

(3) Based on variations of the porosities of different scales in the fracturing energy increasing to exploitation and production processes, extreme huff and puff fluid volumes of the multi-scale spaces of shale oil reservoirs of the multistage fracturing horizontal well in the shale oil reservoir from the fracturing energy increasing to exploitation and production processes can be calculated according to formula (19) to formula (22), as shown in Table 8:

$${V}_{t}^{mic} = V ( {ϕ}_{NMR , w , frac}^{mic} - {ϕ}_{NMR , w , prod}^{mic} ) \qquad ( 19 )$$

$${V}_{t}^{m i n} = V ( {ϕ}_{NMR , w , frac}^{m i n} - {ϕ}_{NMR , w , prod}^{m i n} ) \qquad ( 20 )$$

$${V}_{t}^{mes} = V ( {ϕ}_{NMR , w , frac}^{mes} - {h}_{NMR , w , prod}^{mes} ) \qquad ( 21 )$$

$${V}_{t}^{mac} = V ( {ϕ}_{NMR , w , frac}^{mac} - {ϕ}_{NMR , w , prod}^{mac} ) \qquad ( 22 )$$

where V^{mic}ₜ represents an extreme huff and puff fluid volume of micropores of the multistage fracturing horizontal well in the shale oil reservoir from the fracturing energy increasing to exploitation and production processes, 10⁴ m³; V^{min}ₜ represents an extreme huff and puff fluid volume of minipores of the multistage fracturing horizontal well in the shale oil reservoir from the fracturing energy increasing to exploitation and production processes, 10⁴ m³; V^{mes}ₜ represents an extreme huff and puff fluid volume of mesopores of the multistage fracturing horizontal well in the shale oil reservoir from the fracturing energy increasing to exploitation and production processes, 10⁴ m³; and V^{mac}ₜ represents an extreme huff and puff fluid volume of macropores of the multistage fracturing horizontal well in the shale oil reservoir from the fracturing energy increasing to exploitation and production processes, 10⁴ m³.

TABLE 8
Extreme Huff and Puff Fluid Volumes of Multi-scale spaces of
shale oil reservoirs of Multistage Fracturing Horizontal Well

| | Extreme Huff and Puff Fluid Volumes | | | | |
|---|---|---|---|---|---|
| | of Pores of Different Sizes (10⁴ m³) | | | | |
| SRV | | | | | Total |
| (10⁴ m³) | Micropores | Minipores | Mesopores | Macropores | Pores |
| 800 | 0.338 | 1.429 | 2.319 | 3.563 | 7.648 |

By analysis of Table 8, the total huff and puff fluid volume (58.82 thousand m³) of the macropores in the shale oil reservoir of the target sub-area is obviously higher than the total huff and puff fluid volume (17.67 thousand m³) of the micropores and the minipores. In order to guarantee that the micropores and the minipores play an imbibition role for oil extraction, at least 58.82 thousand m³ fluid should be injected into a single well. The present disclosure gives the usage amount of the fracturing fluid for the fracturing horizontal well in the shale oil reservoir from the perspective of giving full play to the imbibition replacement role of micro-nano pores.

5) A total huff and puff fluid volume of the shale oil reservoir under a condition of any given pressure coefficient is determined.

By formula (23) to formula (27), a conversion coefficient for an overburden-pressure porosity measured with gas and a nuclear magnetic porosity measured with water is calculated; a testing result of the porosity measured with gas and the stress sensitivity (see FIG. 4) under the overburden pressure condition is converted to the nuclear magnetic porosity measured with water, and then the total hull and pull fluid volume in the shale oil reservoir under the condition of any given pressure coefficient in the fracturing energy increasing, exploitation and production, and later energy supplementing processes is determined:

$${k}_{g \to w , res} = \frac{{ϕ}_{g , res}}{{ϕ}_{w , res}} \qquad ( 23 )$$

$${k}_{g \to w} = \frac{{ϕ}_{g , frac}}{{ϕ}_{w , frac}} \qquad ( 24 )$$

$${k}_{g \to w} = \frac{{ϕ}_{g , prod}}{{ϕ}_{w , prod}} \qquad ( 25 )$$

$${k}_{g \to w , sup} = \frac{{ϕ}_{g , sup}}{{ϕ}_{w , sup}} \qquad ( 26 )$$

$${\overline{k}}_{g \to w} = \frac{{k}_{g \to w , res} + {k}_{g \to w , frac} + {k}_{g \to w , prod} + {k}_{g \to w , sup}}{4} \qquad ( 27 )$$

where ϕ_{g,res} represents a porosity measured with gas under the condition of the formation pressure, %; ϕ_{g,frac} represents a porosity measured with gas under the fracturing energy increasing condition, %; ϕ_{g,prod} represents a saturated porosity measured with gas under the exploitation and production condition, %; ϕ_{g,sup} represents a porosity measured with gas under the later energy supplementing condition, %; k_{g→w,res} represents a conversion coefficient for the overburden-pressure porosity measured with gas and the nuclear magnetic porosity measured with water under the condition of the formation pressure, dimensionless; k_{g→w,frac} represents a conversion coefficient for the overburden-pressure porosity measured with gas and the nuclear magnetic porosity measured with water under the fracturing energy increasing condition, dimensionless; k_{g→w,prod} represents a conversion coefficient for the overburden-pressure porosity measured with gas and the nuclear magnetic porosity measured with water under the exploitation and production condition, dimensionless; k_{g→w,sup} represents a conversion coefficient for the overburden-pressure porosity measured with gas and the nuclear magnetic porosity measured with water under the later energy supplementing condition, dimensionless; and k̅_{g→w} represents a conversion coefficient (mean) for the overburden-pressure porosity measured with gas and the nuclear magnetic porosity measured with water under the condition of any given pressure coefficient, dimensionless.

TABLE 9
Conversion Coefficient for Overburden-Pressure Porosity Measured
with Gas and Nuclear Magnetic Porosity Measured with Water

| | | Overburden- | | | |
|---|---|---|---|---|---|
| | | Pressure Porosity | Nuclear Magnetic | | |
| Serial | | Measured with Gas | Porosity Measured | Conversion | |
| Number | Testing Point | (%) | with Water (%) | Coefficient | Mean |
| 1 | Fracturing | 9.943 | 8.513 | 1.168 | 1.163 |
| | Energy | | | | |
| | Increasing | | | | |
| 2 | Formation | 9.003 | 7.815 | 1.152 | |
| | Pressure | | | | |
| 3 | Exploitation | 8.751 | 7.557 | 1.158 | |
| | and Production | | | | |
| 4 | Later Energy | 9.326 | 7.957 | 1.172 | |
| | Supplementing | | | | |

The total huff and puff fluid volume of the shale oil reservoir under the condition of any given pressure coefficient is calculated by formula (28):

$${V}_{t} = V ( \frac{{ϕ}_{g}}{{\overline{k}}_{g \to w}} - {ϕ}_{NMR , w , prod}^{t} ) ; \qquad ( 28 )$$

where ϕ_{g} represents a porosity measured with gas under the condition of any given pressure coefficient, %; and Vₜ the total huff and puff fluid volume of the shale oil reservoir under the condition of any given pressure coefficient, 10⁴ m³.

When the pressure coefficient for fracturing energy increasing reaches 1.94 (corresponding to the testing point with the net pressure of 5 MPa in FIG. 4), under the condition of SRV of 800×10⁴ m³, the total huff and puff fluid volume of the shale oil reservoir from the fracturing energy increasing to exploitation and production processes is calculated according to formula (28) as follows:

$${V}_{t} = 800 \times 1 {0}^{4} {m}^{3} \times ( \frac{9.723}{1.163} - 7.5 \; 57 ) / 100 = 6.45 \times 1 {0}^{4} {m}^{3} .$$

What is claimed is:

1. A method for determining huff and puff fluid volumes in multi-scale spaces of shale oil reservoirs, comprising the following steps:
(1) rock sample pretreatment
1) rock sample selection: selecting 5 standard plunger rock samples of a shale oil reservoir from a same coring interval of a target sub-area, which are marked as shale core 1 #, shale core 2 #, shale core 3 #, shale core 4 #, and shale core 5 #, wherein the shale core 1 # and the shale core 2 # are used for determining a drying temperature and a drying time, and the shale core 3 # is used for porosity stress sensitivity testing, the shale core 4 # is used for determining a time-to-space conversion coefficient, and the shale core 5 # is used for online nuclear magnetic resonance testing; and after selecting and determining the shale core 4 #, averagely cutting the shale core 4 # into two shale cores by wire cutting, wherein the shale core 4 #-1 is used for high pressure hg injection testing, and the shale core 4 #-2 is used for nuclear magnetic resonance testing with saturated simulated formation water;
2) rock sample porosity measurement under overburden pressure: measuring porosities of the shale cores 1 #, 2 #, 3 #, 4 #, and 5 # under an overburden pressure using French VINCE porosity measurement meter, wherein when an average relative error of porosity measurement results of the rock samples is less than 2%, the rock samples selected from the same coring interval have a similar reservoir space feature for carrying out a subsequent experiment; and if the average relative error is greater than 2%, rock samples need to be reselected until the porosity meets a set error requirement;
3) determination of drying temperature and time of rock sample: (a) according to a principle of sequentially increasing by 20° C., setting 8 different drying temperatures 30° C., 50° C., 70° C., 90° C., 110° C., 130° C., 150° C., and 170° C.;
(b) drying the shale core 1 # at the 8 different drying temperatures for 8 hours, and measuring corresponding rock sample masses m₁, m₂, m₃, m₄, m₅, m₆, m₇, and m₈ of the shale core 1 # at the 8 different drying temperatures;
(c) plotting a changing curve of the mass of the shale core 1 # with the drying temperatures, wherein the changing curve of the rock sample mass with the drying temperatures has an inflection point when a mobile fluid in the shale core 1 # is removed completely, and a temperature corresponding to the inflection point is a pretreatment drying temperature Tₒ for the rock samples;
(d) setting 12 different drying times 1 h, 3 h, 5 h, 8 h, 12 h, 24 h, 36 h, 48 h, 72 h, 96 h, 120 h, and 144 h;
(e) drying the shale core 2 # at the pretreatment drying temperature Tₒ according to the 12 different drying times, and measuring corresponding rock sample masses m′₁, m′₂, m′₃, m′₄, m′₅, m′₆, m′₇, m′₈, m′₉, m′₁₀, m′₁₁, and m′₁₂ of the shale core at the 12 different drying times; and
(f) plotting a changing curve of the mass of the shale core 2 # with the drying times, wherein the rock sample mass does not change with the drying times when the mobile fluid in the shale core is removed completely, and then, the corresponding time is a pretreatment drying time t₀;
(2) porosity stress sensitivity testing: measuring porosities of the shale core 3 # under different net pressures using French VINCE overburden-pressure porosity and permeability meter, which comprises the following specific steps:
1) treating the shale core 3 # under the conditions of the pretreatment drying temperature Tₒ and the pretreatment drying time Tₒ;
2) measuring a length, a diameter, and a weight of the shale core 3 #;
3) setting net pressure points for the porosity stress sensitivity testing based on a pressure coefficient change feature in fracturing energy increasing, exploitation and production, and later energy supplementing processes of the shale oil reservoir of the target sub-area, wherein in order to guarantee that net pressure testing points match the three processes, a starting pressure of the net pressure testing points is 2.5 MPa, with an interval of the net pressure testing points being 2.5 or 5 MPa while guaranteeing that a net pressure testing point matches a formation pressure;
4) carrying out the porosity stress sensitivity testing matching the fracturing energy increasing, exploitation and production, and later energy supplementing processes according to the set net pressure testing points; and
5) plotting a changing curve of the porosity with the net pressure in the fracturing energy increasing, exploitation and production, and later energy supplementing processes;
(3) high pressure hg injection testing and nuclear magnetic resonance testing benchmarking
1) treating the shale core 4 # under the conditions of the pretreatment drying temperature Tₒ and the pretreatment drying time t₀;
2) measuring a length, a diameter, and a weight of the shale core 4 #;
3) averagely cutting the shale core into two shale cores by wire cutting, and numbering the two shale cores as shale core 4 #-1 and shale core 4 #-2;
4) carrying out the high pressure hg injection testing on the shale core 4 #-1 using PoreMaster-60 automatic mercury porosimeter, plotting a changing curve of a pore distribution frequency with a pore radius under a condition of semilogarithmic coordinates, and determining a pore distribution characteristic of the shale core 4 #-1; and
5) carrying out nuclear magnetic resonance T₂ spectrum testing on the shale core 4 #-2 using a nuclear magnetic resonance spectrometer after saturation with simulated formation water under formation temperature and pressure conditions, and plotting a changing curve of a number of nuclear magnetic signals with a relaxation time T₂ under the condition of semilogarithmic coordinates;
(4) online nuclear magnetic resonance testing
measuring porosities of the shale core 5 # under different net pressures using an online nuclear magnetic resonance spectrometer, which comprises the following specific steps:
1) treating the shale core 5 # under the conditions of the pretreatment drying temperature Tₒ and the pretreatment drying time t₀;
2) measuring a length, a diameter, and a weight of the shale core 5 #;
3) carrying out nuclear magnetic resonance testing on the shale core 5 # after drying using the online nuclear magnetic resonance spectrometer;
4) putting the shale core 5 # into a core holder, loading a confining pressure of 2 MPa by using a hand pump, and then vacuumizing the rock sample by using a vacuumizing pretreatment system for not less than 48 h;
5) preparing experimental simulated formation water and putting the experimental simulated formation water in a piston container for later use;
6) injecting the simulated formation water in the piston container into the shale core 5 # under a constant pressure using the hand pump; progressively increasing an injection pressure and a confining pressure stepwise in a saturation process and keeping a difference between the confining pressure and the injection pressure at a constant value, and recording an initial reading V₁ of a ruler of the hand pump; when the injection pressure reaches the formation pressure, stopping the saturation process, and recording a reading V₂ of the ruler of the hand pump; keeping the confining pressure consistent with an overlying formation pressure, and regulating the injection pressure by the hand pump, wherein the saturation process of the rock sample is completed in an incubator at a temperature consistent with the formation temperature, with a total saturation time being not less than 48 hours;
7) carrying out nuclear magnetic resonance T₂ spectrum testing on the shale core 5 # using the online nuclear magnetic resonance spectrometer after saturation with the simulated formation water under the formation temperature and pressure conditions;
8) keeping a confining pressure of the core holder consistent with a value of the overlying formation pressure, injecting the simulated formation water into the shale core 5 # using the hand pump for increasing the injection pressure and simulating the fracturing energy increasing process of the actual shale oil reservoir; and when a value of the injection pressure reaches a set pressure coefficient value, stopping the injection process and recording a reading V₃ of the ruler of the hand pump;
9) carrying out nuclear magnetic resonance T₂ spectrum testing on the shale core 5 # using the online nuclear magnetic resonance spectrometer under a condition of completing the simulated fracturing energy increasing for the shale oil reservoir;
10) keeping the confining pressure of the core holder consistent with the value of the overlying formation pressure, reversely turning the hand pump to extract the simulated formation water from the shale core 5 # for reducing the injection pressure and simulating the exploitation and production process of the actual shale oil reservoir; and when the value of the injection pressure reaches the set pressure coefficient value, stopping the extraction process and recording a reading V₄ of the ruler of the hand pump;
11) carrying out nuclear magnetic resonance T₂ testing on the shale core 5 # using the online nuclear magnetic resonance spectrometer under a condition of completing the simulated exploitation and production of the shale oil reservoir;
12) keeping the confining pressure of the core holder consistent with the value of the overlying formation pressure, injecting the simulated formation water into the shale core 5 # using the hand pump for increasing the injection pressure and simulating the later energy supplementing process of the actual shale oil reservoir; and when the value of the injection pressure reaches the set pressure coefficient value, stopping the injection process and recording a reading V₅ of the ruler of the hand pump; and
13) carrying out nuclear magnetic resonance T₂ spectrum testing on the shale core 5 # using the online nuclear magnetic resonance spectrometer under a condition of completing the simulated later energy supplementing for the shale oil reservoir;
(5) data processing and analysis
1) calculating a time-to-space conversion coefficient for a nuclear magnetic resonance relaxation time T₂ and a pore size;
2) establishing a calibration relationship of a number of nuclear magnetic resonance T₂ spectrum signals to a shale porosity with saturated simulated formation water;
3) determining a total huff and puff fluid volume of reservoir spaces in the shale oil reservoir;
4) determining huff and puff fluid volumes of multi-scale spaces of the shale oil reservoir; and
5) determining a total huff and puff fluid volume of the shale oil reservoir under a condition of any given pressure coefficient.

2. The method for determining huff and puff fluid volumes in multi-scale spaces of shale oil reservoirs according to claim 1, wherein 1) in step (5) comprises the following steps:
(a) extracting the high pressure hg injection testing data, namely pore radius and pore distribution frequency data, of the shale core 4 #, and plotting the changing curve of the pore distribution frequency with the pore radius under the condition of semilogarithmic coordinates;
(b) extracting the data of the nuclear magnetic resonance relaxation time T₂ and the number of nuclear magnetic signals of the shale core 5 # after saturation with the simulated formation water under the formation temperature and pressure conditions, and plotting the changing curve of the number of nuclear magnetic signals with the relaxation time T₂ under the condition of semilogarithmic coordinates;
(c) integrating the curve data of steps (a) and (b) in a same coordinate system, and establishing a time-to-space conversion curve of the nuclear magnetic resonance relaxation time T₂ and a high pressure hg injection pore radius, wherein an X-axis bottom coordinate represents the pore radius and a Y-axis principal coordinate represents the pore distribution frequency; an X-axis top coordinate represents the relaxation time T₂ and a Y-axis auxiliary coordinate represents the number of nuclear magnetic signals; and
(d) calculating the time-to-space conversion coefficient starting from a relaxation time corresponding to a second peak because a first peak of the nuclear magnetic resonance T₂ spectrum after the shale core sample is saturated with the simulated formation water represents organic matter signal display, and recording the values of the nuclear magnetic resonance relaxation time T₂ᵢ and the pore radius rᵢ when nuclear magnetic signal peaks correspond to pore distribution frequency peaks of high pressure hg injection one to one; and calculating the time-to-space conversion coefficient for the value of the nuclear magnetic resonance relaxation time T₂ and the pore size of the shale core sample:
$${k}_{𝔠 s} = \frac{{k}_{𝔠 s 1} + {k}_{𝔠 s 2} + {k}_{𝔠 s i} + … + {k}_{𝔠 s n}}{n} \qquad ( 1 )$$
wherein kₜₛ represents the time-to-space conversion coefficient for the nuclear magnetic resonance relaxation time T₂ and the pore size, nn/ms; kₜₛᵢ represents the time-to-space conversion coefficient for the nuclear magnetic resonance relaxation time T₂ and the pore size under a condition of an ith corresponding peak, nm/ms; and n represents a number of nuclear magnetic signals and corresponding peaks of the pore distribution frequency of high pressure hg injection.

3. The method for determining huff and puff fluid volumes in multi-scale spaces of shale oil reservoirs according to claim 1, wherein 2) in step (5) comprises the following steps:
(a) based on a fluid volume injected by the hand pump in step (4), calculating, using a volumetric method, porosities of the shale core 5 # saturated with the simulated formation water under the formation temperature and pressure, fracturing energy increasing, exploitation and production, and later energy supplementing conditions, with calculation formulas being as follows:
$${ϕ}_{w , res} = ( {V}_{2} - {V}_{1} ) / ( \frac{π {d}^{2} L}{4} ) \times 100 \% = \frac{4 ( {V}_{2} - {V}_{1} )}{π {d}^{2} L} \times 100 \% \qquad ( 2 )$$
$${ϕ}_{w , ftac} = ( {V}_{3} - {V}_{1} ) / ( \frac{π {d}^{2} L}{4} ) \times 100 \% = \frac{4 ( {V}_{3} - {V}_{1} )}{π {d}^{2} L} \times 100 \% \qquad ( 3 )$$
$${ϕ}_{w , prod} = ( {V}_{4} - {V}_{1} ) / ( \frac{π {d}^{2} L}{4} ) \times 100 \% = \frac{4 ( {V}_{4} - {V}_{1} )}{π {d}^{2} L} \times 100 \% , \qquad ( 4 )$$
$${ϕ}_{w , sup} = ( {V}_{5} - {V}_{1} ) / ( \frac{π {d}^{2} L}{4} ) \times 100 \% = \frac{4 ( {V}_{5} - {V}_{1} )}{π {d}^{2} L} \times 1 \; 00 \% , \qquad ( 5 )$$
wherein ϕ_{w,res} represents a measured porosity with the saturated simulated formation water under the formation temperature and pressure conditions, %; V₁ represents the initial reading of the ruler of the hand pump, mL; V₂ represents a reading of the ruler of the hand pump when the injection pressure reaches the formation pressure, mL; ϕ_{w,frac} represents a measured porosity with the saturated simulated formation water under the fracturing energy increasing condition, %; V₃ represents a reading of the ruler of the hand pump when the injection pressure reaches a set pressure coefficient value for fracturing energy increasing, mL; ϕ_{w,prod} represents a measured porosity with the saturated simulated formation water under the exploitation and production condition, %; V₄ represents a reading of the ruler of the hand pump when the injection pressure reaches a set pressure coefficient value for exploitation and production, mL; ϕ_{w,sup} represents a measured porosity with the saturated simulated formation water under the later energy supplementing condition, %; V₅ represents a reading of the ruler of the hand pump when the injection pressure reaches a set pressure coefficient value for later energy supplementing, mL; d represents a rock sample diameter, cm; and L represents a rock sample length, cm; and
(b) based on the nuclear magnetic resonance T₂ spectrum signals after saturation with the simulated formation water in step (4), converting T₂ spectrum signal components of the shale after saturation with the simulated formation water under the formation temperature and pressure, fracturing energy increasing, exploitation and production, and later energy supplementing conditions to porosity components according to formulas (6), (7), (8), and (9):
$${ϕ}_{NMR , w , res} {\vert}_{{T}_{2}} = \frac{{S}_{w , res} {ϕ}_{w , res}}{{S}_{a c , w , res} - {S}_{a c , d}} \times 100 \% \qquad ( 6 )$$
$${ϕ}_{NMR , w , frac} {\vert}_{{T}_{2}} = \frac{{S}_{w , frac} {ϕ}_{w , frac}}{{S}_{a c , w , frac} - {S}_{a c , d}} \times 100 \% ; \qquad ( 7 )$$
$${ϕ}_{NMR , w , prod} {\vert}_{{T}_{2}} = \frac{{S}_{w , prod} {ϕ}_{w , prod}}{{S}_{a c , w , prod} - {S}_{a c , d}} \times 100 \% \qquad ( 8 )$$
$${ϕ}_{NMR , w , sup} {\vert}_{{T}_{2}} = \frac{{S}_{w , sup} {ϕ}_{w , sup}}{{S}_{a c , w , sup} - {S}_{a c , d}} \times 100 \% \qquad ( 9 )$$
wherein ϕ_{NMR,w,res}|_{T2} represents a porosity component after saturation with the simulated formation water under the formation temperature and pressure conditions, %; S_{w,res} represents a nuclear magnetic signal component after saturation with the simulated formation water under the formation temperature and pressure conditions, PU; S_{ac,w,res} represents an accumulated number of nuclear magnetic signals after saturation with the simulated formation water under the formation temperature and pressure conditions, PU; ϕ_{NMR,w,frac}|_{T2} represents a porosity component after saturation with the simulated formation water under the fracturing energy increasing condition, %; S_{w,frac} represents a nuclear magnetic signal component after saturation with the simulated formation water under the fracturing energy increasing condition, PU; S_{ac,w,frac} represents an accumulated number of nuclear magnetic signals after saturation with the simulated formation water under the fracturing energy increasing condition, PU; ϕ_{NMR,w,prod}|_{T2} represents a porosity component after saturation with the simulated formation water under the exploitation and production condition, %; S_{w,prod} represents a nuclear magnetic signal component after saturation with the simulated formation water under the exploitation and production condition, PU; S_{ac,w,prod} represents an accumulated number of nuclear magnetic signals after saturation with the simulated formation water under the exploitation and production condition, PU; ϕ_{NMR,w,sup}|_{T2} represents a porosity component after saturation with the simulated formation water under the later energy supplementing condition, %; S_{w,sup} represents a nuclear magnetic signal component after saturation with the simulated formation water under the later energy supplementing condition, PU; S_{ac,w,sup} represents an accumulated number of nuclear magnetic signals after saturation with the simulated formation water under the later energy supplementing condition, PU; and S_{ac,d} represents an accumulated number of nuclear magnetic signals after drying the shale core 5 #, PU.

4. The method for determining huff and puff fluid volumes in multi-scale spaces of shale oil reservoirs according to claim 1, wherein 3) in step (5) comprises the following steps:
(a) based on the porosity components calculated by formula (6) to formula (9), plotting changing relationship curves of the porosity components and accumulated values of the porosity components of the shale saturated with the simulated formation water under the formation temperature and pressure, fracturing energy increasing, exploitation and production, and later energy supplementing conditions with the relaxation time T₂, respectively;
(b) based on the time-to-space conversion coefficient kₜₛ for the nuclear magnetic resonance relaxation time T₂ and the pore size determined by formula (1), calculating pore diameters corresponding to different relaxation times T₂ under the formation temperature and pressure, fracturing energy increasing, exploitation and production, and later energy supplementing conditions, and plotting changing relationship curves of the porosity components and accumulated values of the porosity components of the shale saturated with the simulated formation water with the relaxation time T₂ and the pore diameter in the same coordinate system, wherein an X-axis bottom coordinate represents the relaxation time T₂ and a Y-axis principal coordinate represents the porosity component; an X-axis top coordinate represents the pore diameter and a Y-axis auxiliary coordinate represents the accumulated value of the porosity components; and
(c) based on the changing relationship curves of the porosity components and accumulated values of the porosity components of the shale saturated with the simulated formation water with the relaxation time T₂ and the pore diameter obtained in the previous step, calculating a total huff and puff fluid volume of a multistage fracturing horizontal well in the shale oil reservoir from the fracturing energy increasing to exploitation and production processes, as shown in the following formula:
Vₜ=V(ϕ_{NMR,w,frac}^{t}−ϕ_{NMR,w,prod}^{t}) (10);
wherein Vₜ represents the total huff and puff fluid volume of the multistage fracturing horizontal well in the shale oil reservoir from the fracturing energy increasing to exploitation and production processes, 10⁴ m³; V represents a stimulated reservoir volume (SRV) of the multistage fracturing horizontal well in the shale oil reservoir, 10⁴ m³; ϕ^{t}_{NMR,w,frac} represents an accumulated value of the porosity components after saturation with the simulated formation water under the fracturing energy increasing condition, %; and ϕ^{t}_{NMR,w,prod} represents an accumulated value of the porosity components after saturation with the simulated formation water under the exploitation and production condition, %.

5. The method for determining huff and puff fluid volumes in multi-scale spaces of shale oil reservoirs according to claim 1, wherein 4) in step (5) comprises:
with 0.01 μm, 0.1 μm, and 1 μm as boundaries of micropores, minipores, mesopores, and macropores, explaining calculation processes of the huff and puff fluid volumes of the multi-scale spaces of the shale oil reservoir, which comprises the following steps:
(a) based on the time-to-space conversion coefficient kₜₛ, calculating dividing values of the relaxation time T₂ corresponding to divided radii of micropores, minipores, mesopores, and macropores, namely the values T_{2,10nm}, T_{2,100nm}, and T_{2,1000nm} of the relaxation time T₂ corresponding to 10 nm, 100 nm, and 1000 nm;
(b) based on the values T_{2,10nm}, T_{2,100nm}, and T_{2,1000nm}, calculating porosities ϕ^{mic}_{NMR,w,frac}, ϕ^{min}_{NMR,w,frac}, ϕ^{mes}_{NMR,w,frac}, and ϕ^{mac}_{NMR,w,frac} of micropores, minipores, mesopores, and macropores after saturation with the simulated formation water under the fracturing energy increasing condition and porosities ϕ^{mic}_{NMR,w,prod}, ϕ^{min}_{NMR,w,prod}, ϕ^{mes}_{NMR,w,prod}, and ϕ^{mac}_{NMR,w,prod} of micropores, minipores, mesopores, and macropores after saturation with the simulated formation water under the exploitation and production condition by formulas (11)-(18);
$${ϕ}_{NMR , w , frac}^{mic} = \frac{{S}_{w , frac} {\vert}_{{T}_{2 , 10 n m}} \times {ϕ}_{w , frac}}{{S}_{a c , w , frac} - {S}_{a c , d}} \qquad ( 11 )$$
$${ϕ}_{NMR , w , frac}^{m i n} = \frac{( {S}_{w , frac} {\vert}_{{T}_{2 , 100 n m}} - {S}_{w , frac} {\vert}_{{T}_{2 , 10 n m}} ) \times {ϕ}_{w , frac}}{{S}_{a c , w , frac} - {S}_{a c , d}} \qquad ( 12 )$$
$${ϕ}_{NMR , w , frac}^{mes} = \frac{( {S}_{w , frac} {\vert}_{{T}_{2 , 1000 n m}} - {S}_{w , frac} {\vert}_{{T}_{2 , 100 n m}} ) \times {ϕ}_{w , frac}}{{S}_{a c , w , frac} - {S}_{a c , d}} \qquad ( 13 )$$
$${ϕ}_{NMR , w , frac}^{mac} = \frac{( {S}_{a c , w , frac} - {S}_{w , frac} {\vert}_{{T}_{2 , 1000 n m}} ) \times {ϕ}_{w , frac}}{{S}_{a c , w , frac} - {S}_{a c , d}} \qquad ( 14 )$$
$${ϕ}_{NMR , w , prod}^{mic} = \frac{{S}_{w , prod} {\vert}_{{T}_{2 , 10 n m}} \times {ϕ}_{w , prod}}{{S}_{a c , w , prod} - {S}_{a c , d}} \qquad ( 15 )$$
$${ϕ}_{NMR , w , prod}^{m i n} = \frac{( {S}_{w , prod} {\vert}_{{T}_{2 , 100 n m}} - {S}_{w , prod} {\vert}_{{T}_{2 , 10 n m}} ) \times {ϕ}_{w , prod}}{{S}_{a c , w , prod} - {S}_{a c , d}} \qquad ( 16 )$$
$${ϕ}_{NMR , w , prod}^{mes} = \frac{( {S}_{w , prod} {\vert}_{{T}_{2 , 1000 n m}} - {S}_{w , prod} {\vert}_{{T}_{2 , 100 n m}} ) \times {ϕ}_{w , prod}}{{S}_{a c , w , prod} - {S}_{a c , d}} \qquad ( 17 )$$
$${ϕ}_{N M R , w , p r o d}^{mac} = \frac{( {S}_{a c , w , prod} - {S}_{w , prod} {\vert}_{{T}_{2 , 1000 n m}} ) \times {ϕ}_{w , prod}}{{S}_{a c , w , prod} - {S}_{a c , d}} \qquad ( 18 )$$
wherein S_{w,frac}|_{T2,10nm} represents an accumulated value of the nuclear magnetic signals of micropores after saturation with the simulated formation water under the fracturing energy increasing condition, PU; S_{w,frac}|_{T2,100nm} represents an accumulated value of the nuclear magnetic signals of minipores after saturation with the simulated formation water under the fracturing energy increasing condition, PU; S_{w,frac}|_{T2,1000nm} represents an accumulated value of the nuclear magnetic signals of mesopores after saturation with the simulated formation water under the fracturing energy increasing condition, PU; S_{w,prod}|_{T2,10nm} represents an accumulated value of the nuclear magnetic signals of micropores after saturation with the simulated formation water under the exploitation and production condition, PU; S_{w,prod}|_{T2,100nm} represents an accumulated value of the nuclear magnetic signals of minipores after saturation with the simulated formation water under the exploitation and production condition, PU; and S_{w,prod}|_{T2,1000nm} represents an accumulated value of the nuclear magnetic signals of mesopores after saturation with the simulated formation water under the exploitation and production condition, PU; and
(c) based on variations of the porosities of different scales in the fracturing energy increasing to exploitation and production processes, calculating extreme huff and puff fluid volumes of the multi-scale spaces of shale oil reservoirs of the multistage fracturing horizontal well in the shale oil reservoir from the fracturing energy increasing to exploitation and production processes according to formula (19) to formula (22);
$${V}_{t}^{mic} = V ( {ϕ}_{NMR , w , frac}^{mic} - {ϕ}_{NMR , w , prod}^{mic} ) \qquad ( 19 )$$
$${V}_{t}^{m i n} = V ( {ϕ}_{NMR , w , frac}^{m i n} - {ϕ}_{NMR , w , prod}^{m i n} ) \qquad ( 20 )$$
$${V}_{t}^{mes} = V ( {ϕ}_{NMR , w , frac}^{mes} - {ϕ}_{NMR , w , prod}^{mes} ) \qquad ( 21 )$$
$${V}_{t}^{mac} = V ( {ϕ}_{NMR , w , frac}^{mac} - {ϕ}_{NMR , w , prod}^{mac} ) \qquad ( 22 )$$
wherein V^{mic}ₜ represents an extreme huff and puff fluid volume of micropores of the multistage fracturing horizontal well in the shale oil reservoir from the fracturing energy increasing to exploitation and production processes, 10⁴ m³; V^{min}ₜ represents an extreme huff and puff fluid volume of minipores of the multistage fracturing horizontal well in the shale oil reservoir from the fracturing energy increasing to exploitation and production processes, 10⁴ m³; V^{mes}ₜ represents an extreme huff and puff fluid volume of mesopores of the multistage fracturing horizontal well in the shale oil reservoir from the fracturing energy increasing to exploitation and production processes, 10⁴ m³; and V^{mac}ₜ represents an extreme huff and puff fluid volume of macropores of the multistage fracturing horizontal well in the shale oil reservoir from the fracturing energy increasing to exploitation and production processes, 10⁴ m³.

6. The method for determining huff and puff fluid volumes in multi-scale spaces of shale oil reservoirs according to claim 1, wherein 5) in step (5) comprises the following steps:
by formula (23) to formula (27), calculating a conversion coefficient for an overburden-pressure porosity measured with gas and a nuclear magnetic porosity measured with water, converting a testing result of the porosity measured with gas and the stress sensitivity under the overburden pressure condition to the nuclear magnetic porosity measured with water, and then determining the total hull and pull fluid volume in the shale oil reservoir under the condition of any given pressure coefficient in the fracturing energy increasing, exploitation and production, and later energy supplementing processes;
$${k}_{g \to w , res} = \frac{{ϕ}_{g , res}}{{ϕ}_{w , res}} \qquad ( 23 )$$
$${k}_{g \to w} = \frac{{ϕ}_{g , frac}}{{ϕ}_{w , frac}} \qquad ( 24 )$$
$${k}_{g \to w} = \frac{{ϕ}_{g , prod}}{{ϕ}_{w , prod}} \qquad ( 25 )$$
$${k}_{g \to w , sup} = \frac{{ϕ}_{g , sup}}{{ϕ}_{w , sup}} \qquad ( 26 )$$
$${\overline{k}}_{g \to w} = \frac{{k}_{g \to w , res} + {k}_{g \to w , frac} + {k}_{g \to w , prod} + {k}_{g \to w , sup}}{4} \qquad ( 27 )$$
wherein ϕ_{g,res} represents a porosity measured with gas under the condition of the formation pressure, %; ϕ_{g,frac} represents a porosity measured with gas under the fracturing energy increasing condition, %: ϕ_{g,prod} represents a saturated porosity measured with gas under the exploitation and production condition, %; ϕ_{g,sup} represents a porosity measured with gas under the later energy supplementing condition, %; k_{g→w,res} represents a conversion coefficient for the overburden-pressure porosity measured with gas and the measured porosity with the saturated simulated formation water under the condition of the formation pressure, dimensionless; k_{g→w,frac} represents a conversion coefficient for the overburden-pressure porosity measured with gas and the nuclear magnetic porosity measured with water under the fracturing energy increasing condition, dimensionless; k_{g→w,prod} represents a conversion coefficient for the overburden-pressure porosity measured with gas and the nuclear magnetic porosity measured with water under the exploitation and production condition, dimensionless; k_{g→w,sup} represents a conversion coefficient for the overburden-pressure porosity measured with gas and the nuclear magnetic porosity measured with water under the later energy supplementing condition, dimensionless; and k̅_{g→w} represents a conversion coefficient for the overburden-pressure porosity measured with gas and the nuclear magnetic porosity measured with water under the condition of any given pressure coefficient, dimensionless; and
the total huff and puff fluid volume of the shale oil reservoir under the condition of any given pressure coefficient is calculated by formula (28):
$${V}_{t} = V ( \frac{{ϕ}_{g}}{{\overline{k}}_{g \to w}} - {ϕ}_{NMR , w , prod}^{t} ) \qquad ( 28 )$$
wherein ϕ_{g} represents a porosity measured with gas under the condition of any given pressure coefficient, %; and Vₜ the total huff and puff fluid volume of the shale oil reservoir under the condition of any given pressure coefficient, 10⁴ m³.
